(19) United States
(12) Patent Application Publication
(10) Pub. No.: US 2008/0062013 A1
(43) Pub. Date: Mar. 13, 2008

(54) Wall switch for wired and self-powered wireless controllers with recessed and flush mounting

(76) Inventors: Bradbury R. Face, Norfolk, VA (US); Glenn F. Rogers JR., Hampton, VA (US)

Correspondence Address: David J. Bolduc;Face International Corporation, 427 West 35th Street, Norfolk, VA, 23508, US

(21) Appl. No.: 11/716,981

(22) Filed: Mar. 12, 2007

Related U.S. Application Data
(60) Provisional application No. 60/781,035, filed on Mar. 10, 2006.

(51) Int. Cl. H03K 17/94; H01H 33/02

(52) U.S. Cl. 341/20; 340/825.72; 307/119; 200/237

(57) ABSTRACT

A self-powered switching system using electromechanical generators generates power for activation of a latching relay. The electromechanical generators comprise electroactive elements that may be mechanically actuated to generate electrical power. The associated signal generation circuitry may be coupled to a transmitter or transceiver for sending and/or receiving RF signals to/from a receiver which actuates the latching relay. Power may be stored within the circuit using rechargeable batteries for powering or supplementing power to the transmitter or transceiver. The self-powered switches are included in multi-gang configurations for installation with one or more conventional wired switches. The single or multigang switches may be mounted on the wall surface. Alternately the single or multigang switch may be mounted in a flange or bracket and recessed into a hole in the wall to provide a narrower mounted profile.

The present U.S. Utility patent application claims priority pursuant to 35 U.S.C. 119(e) to U.S. Provisional patent application Ser. No. 60/781,035 filed Mar. 10, 2006 entitled “Multi-Gang Wall Switch for Wired and Self-Powered Wireless Controllers”, which Provisional Application is hereby incorporated by reference in its entirety and is made part of the present U.S. Utility patent application.

### BACKGROUND OF THE INVENTION

1. Field of the Invention

The present invention relates generally to switching devices for energizing lights, appliances and the like. More particularly, the present invention relates to a Multi-Gang Wall Switch for Wired and Self-Powered Wireless Control of electrical appliances, i.e., incorporating both a conventional wired switch and a wireless switch for energizing lights, appliances and the like. The multi-gang switch has at least one conventional wired switch and at least one self-powered switch initiator device to generate an activation signal for a latching relay. The power for the wireless switch portion is generated through an electroactive element and is sent through signal generation circuitry coupled to a transmitter for sending one or more unique and/or coded RF signals to one or more receivers that actuate the latching relay. By including a wireless switch in a wall mounting plate with an adjacent wall switch for connection to 110V house electricity, conventional single- and multiple-gang powered wall switches may be reconfigured as multiple gang switches having a greater number of functions, without having to rewire or replace the existing switch. The switch includes a surface mounted as well as a recessed mounted wireless switch.

2. Description of the Prior Art

Switches and latching relays for energizing lights, appliances and the like are well known in the prior art. Typical light switches comprise, for example, single-pole switches and three-way switches. A single-pole switch has two terminals that are hot leads for an incoming line (power source) and an outgoing line to the light. Three-way switches can control one light from two different places. Each three-way switch has three terminals: the common terminal and two traveler terminals. A typical pair of three-way switches uses two boxes each having two cables with the first box having an incoming line from a power source and an outbound line to the second box, and the second box having the incoming line from the first box and an outbound line to the light.

In each of these switching schemes it is often necessary to drill holes and mount switches and junction boxes for the outlets as well as to run cable. Drilling holes and mounting switches and junction boxes can be difficult and time consuming. Also, running electrical cable requires starting at a fixture, pulling cable through holes in the framing to each fixture in the circuit, and continuing all the way back to the service panel. Though simple in theory, getting cable to cooperate can be difficult and time consuming. Cable often kinks, tangles or binds while pulling, and needs to be straightened out somewhere along the run.

Remotely actuated switches/relays are also known in the art. Known remote actuation controllers include tabletop controllers, wireless remotes, timers, motion detectors, voice activated controllers, and computers and related software. For example, remote actuation means may include receiver modules that are plugged into a wall outlet and into which a power cord for a device may be plugged. The device can then be turned on and off by a remote controller/transmitter. Other remote actuation means include screw-in lamp receiver modules wherein the receiver module is screwed into a light socket, and then a bulb screwed into the receiver module. The light can be turned on and off and can be dimmed or brightened by a remote controller/transmitter.

Another example of one type of remote controller for the above described modules is a radio frequency (RF) base transceiver. With these controllers, a transceiver base is plugged into an outlet and can control groups of receiver modules in conjunction with a hand held wireless RF remote. RF repeaters may be used to boost the range of compatible wireless remote transmitters, switches and security system sensors by up to 150 ft. per repeater. The transceiver base is required for these wireless RF remote control systems and allows control of several lamps or appliances. Batteries are also required in the hand held wireless remote control systems.

Rather than using a hand held RF remote transmitter, remote wall transmitters may be used. These wall transmitters, which are up to ¾″ thick, are affixed to a desired location with an adhesive or fastener. In conjunction with a transceiver base unit (plugged into a 10V receptacle) the remote wall transmitter may control compatible receiver/transceiver modules and their associated switches. The wireless transmitters send an RF signal to the transceiver base unit and the transceiver base unit then transmits a signal along the existing 110V wiring in the home to compatible switches or receiver modules. Each switch can be programmed with an addressable signal. Wireless transmitters also require batteries.

These remotes control devices may also control, for example, audio/video devices such as the TV, VCR, and stereo system, as well as lights and other devices using an RF to infrared (IR) base. The RF remote can control audio/video devices by sending proprietary RF commands to a converter that translates the commands to IR. IR commands are then sent to the audio/video equipment. The infrared (IR) base responds to infrared signals from the infrared remotes and then transmits equivalent commands to compatible receivers.

A problem with conventional wall switches is that extensive wiring must be run both from the switch boxes to the lights and from the switch boxes to the power source in the service panels.

Another problem with conventional wall switches is that additional wiring must be run for lights controlled by more than one switch.

Another problem with conventional wall switches is that the voltage lines are present as an input to and an output from the switch.

Another problem with conventional wall switches is the cost associated with initial installation of wire to, from and between switches.

Another problem with conventional wall switches is the cost and inconvenience associated with remodeling, relocating or rewiring existing switches.

A problem with conventional RF transmitters is that they require an external power source such as high voltage AC power or batteries.

Another problem with conventional battery-powered RF transmitters is the cost and inconvenience associated with replacement of batteries.

Another problem with conventional AC-powered RF transmitters is the difficulty when remodeling in rewiring or relocating a wall transmitter.

Another problem with conventional RF switching systems is that a pair comprising a transmitter and receiver must generally be purchased together.

Another problem with conventional RF switching systems is that transmitters may inadvertently activate incorrect receivers.

Another problem with conventional RF switching systems is that receivers may accept an activation signal from only one transmitter.

Another problem with conventional RF switching systems is that transmitters may activate only one receiver.

Another problem with conventional RF switching systems is that the existing wired switch must be removed to install the RF switch in its place.

Accordingly, it would be desirable to provide a network of switch initiators and/or latching relay devices that overcomes the aforementioned problems of the prior art.

### SUMMARY OF THE INVENTION

The present invention provides one or more self-powered switching initiators or latching relay devices, each using an electroactive generator or transducer, packaged in a wall mounting frame with one or more conventional powered wall switches. The self-powered portion of the switch may be mounted flush to a wall using a frame, or in the alternative may be recessed into a hole in the wall to provide a narrower mounted profile. The electroactive element in the generator is capable of deforming with a high amount of bending displacement, and when deformed by a mechanical impulse generates an electric field. The electroactive transducer is used as an electro-mechanical converter/generator for generating an electrical signal that, with the accompanying circuitry, generates an RF signal that initiates a latching or relay mechanism. The latching or relay mechanism thereby turns electrical devices such as lights and appliances on and off or provides an intermediate or dimming signal, or initiates other functions.

The mechanical actuating means for the electroactive generator element applies a suitable mechanical impulse to the electroactive generator element in order to generate an electrical signal, such as a pulse, multiple pulses and/or waves having sufficient magnitude and duration to power and actuate downstream circuit components. A mechanism similar to a light switch, for example, may apply pressure through a toggle, snap action, paddle, plunger, plucking or ratchet mechanism. Larger or multiple electroactive generator elements may also be used to generate the electrical signal. Co-owned U.S. Pat. No. 6,630,894 entitled “Self-Powered Switching Device,” which is hereby incorporated by reference, discloses a self-powered switch where the electroactive element generates an electrical pulse. Co-owned U.S. Pat. No. 6,812,594 entitled “Self-Powered Trainable Switching Network,” which is hereby incorporated by reference, discloses a network of switches such as that disclosed in U.S. Pat. No. 6,630,894, with the modification that the switches and receivers are capable accepting a multiplicity of coded RF signals. Co-owned U.S. Pat. No. 7,084,529 entitled “Self-Powered Switch Initiation System,” which is hereby incorporated by reference, discloses a network of switches such as that disclosed in U.S. Pat. Nos. 6,630,894 and 6,812,594, with additional modifications to the coded RF signals, multiple training topologies, and an improved mounting and actuation means, as well as circuitry to support the output electrical signal of the transducer.

In the present invention, modifications have been developed to the electroactive element, its mounting and its mechanical actuator, resulting in a modification in the character of the electrical signal produced by the transducer. The present invention describes a self-powered switch initiation system having an electroactive element and accompanying circuitry designed to work with an oscillating electrical signal. To harness the power generated by the electroactive element, the accompanying RF signal generation circuitry has also been modified to use the electrical signal most efficiently. Additionally, the use of rechargeable batteries may improve the usefulness, life and efficiency of the circuit.

In one embodiment of the invention, the electroactive generator output signal powers an RF transmitter which sends an RF signal to an RF receiver which then actuates the relay. In yet another embodiment, the electromagnetic or electroactive generator output signal powers a transmitter, which sends a pulsed (coded) RF signal to an RF receiver which then actuates the relay. Digitized RF signals are coded (as with a garage door opener) to only activate the relay that is coded with that digitized RF signal. The transmitters may be capable of developing one or more coded RF signals and the receivers likewise are capable of receiving one or more coded RF signal. Furthermore, the receivers are “trainable” to accept coded RF signals from new or multiple transmitters. In another embodiment of the invention, rechargeable batteries are used to capture some of the electrical output of the generator and apply the stored energy to circuit components. Another embodiment of the invention uses a transceiver in conjunction with the battery and transmission circuit to send and receive RF signal within the system. Lastly, the mounting method for the transmitter has been modified to include flush-mounted and recess mounted frames used in conjunction with at least one wireless transmitter and/or one conventional wired switch device.

Accordingly, it is a primary object of the present invention to provide a multi-gang switching system in which an electroactive or piezoelectric element is used to power an RF transmitter for activating an electrical device in conjunction with a second powered switch for activating an electrical device.

It is another object of the present invention to provide a device of the character described in which transmitters may be installed without necessitating additional wiring.

It is another object of the present invention to provide a device of the character described in which transmitters may be installed without cutting holes into the building structure.

It is another object of the present invention to provide a device of the character described in which the additional self-powered transmitters do not require external electrical input such as 120 or 220 VAC or batteries.

It is another object of the present invention to provide a device of the character described incorporating an electroactive converter that generates an electrical signal of sufficient duration and magnitude to activate a radio frequency transmitter for activating a latching relay and/or switch initiator.

It is another object of the present invention to provide a device of the character described incorporating a transmitter that is capable of developing at least one coded RF signal.

It is another object of the present invention to provide a device of the character described incorporating a receiver capable of receiving at least one coded RF signal from at least one transmitter.

It is another object of the present invention to provide a device of the character described incorporating a receiver capable of “learning” to accept coded RF signals from one or more transmitters.

It is another object of the present invention to provide a device of the character described for use in actuating, operating or altering the state of lighting, appliances, security devices and other electrical and electromechanical fixtures in a building.

Further objects and advantages of the invention will become apparent from a consideration of the drawings and ensuing description thereof.

### BRIEF DESCRIPTION OF THE DRAWINGS

FIG. 1 is an elevation view showing the details of construction of a flextensional piezoelectric transducer used in the present invention, as an electroactive generator;

FIG. 1a is an elevation view showing the details of construction of the flextensional piezoelectric generator of FIG. 1 having an additional prestress layer;

FIG. 2 is an elevation view showing the details of construction of an alternate multi-layer flextensional piezoelectric generator used in a modification of the present invention;

FIG. 2a is an elevation view showing the details of construction of the flextensional piezoelectric generator of FIG. 1a with a flat rather than arcuate profile;

FIG. 3 is an elevation showing the electrical connections to a multilayer flextensional piezoelectric generator;

FIG. 4 is an elevation view of the actuating device of the present invention for generation of an electrical signal by deflecting a flextensional piezoelectric generator;

FIG. 5 is an elevation view of the preferred mounting and actuating device of the present invention for generation of an electrical signal by deflecting a flextensional piezoelectric generator;

FIG. 6 is an elevation view of an alternate mounting and actuating device of the present invention for generation of an electrical signal by deflecting a flextensional piezoelectric generator of FIG. 2a;

FIGS. 7a-7c show an alternate clamping mechanism for retention of an end of the flextensional piezoelectric generator of FIG. 2a in undeflected and deflected states;

FIGS. 8a and 8b are elevation views of the preferred deflector assembly of the present invention showing the transducer in the undeflected and deflected positions respectively;

FIG. 8c is a plan view of the preferred deflector assembly of the present invention showing the transducer in the undeflected position;

FIGS. 9a-e are elevation views of one embodiment of a plucker paddle mechanism as in FIGS. 8a-c, deflecting the end of an electroactive generator, and rotating/cocking to a reset position;

FIGS. 10a-c show the electrical signal generated by the transducer, the electrical output signal of the rectifier at the junction with the capacitor and the regulated electrical signal respectively;

FIG. 11 is a plan view of a face plate and switch housing having two membrane switches thereon for direct connection to a transmitter circuit to provide separate functions;

FIG. 12 is a plan view of the face plate and switch housing of FIG. 11 showing a deflection assembly and piezoelectric generator in ghost therein;

FIG. 13 is a plan view of a domed contact switch showing disconnected concentric circuit traces, with the domed contact in ghost thereabove;

FIG. 14 is a plan view of a contact switch showing disconnected interdigitated circuit traces, with the shorting contact in ghost thereabove;

FIG. 15 is a side elevation view of the face plate and switch housing of FIG. 12;

FIG. 16 is a side elevation view of the face plate and switch housing of FIG. 15 having a larger wall mount surrounding the central switch button;

FIG. 17 is a side elevation view of a conventional wired wall switch superimposed over the side elevation view of FIG. 16;

FIG. 18 is a side elevation view of a modified embodiment of the switch in FIG. 16 having a faceplate that conforms to the elevation of the conventional wired switch of FIG. 17 and mountable adjacently or within the same wall mounting frame as the conventional wired switch of FIG. 17;

FIG. 19a is a plan view of a single function toggle wireless switch as in FIG. 18 of the switch in FIG. 16 having a faceplate that conforms to the elevation of the conventional wired switch of FIG. 17;

FIG. 19b is a plan view of an alternate single function toggle wireless switch as in FIG. 18 of the switch in FIG. 16 having a faceplate that conforms to the elevation of the conventional wired switch of FIG. 17 having a smaller central hole through which extends only the elevated portion of the button;

FIGS. 20a and 20b are exploded and assembled elevation views of a recess mounted transmitter of FIGS. 19a and 19b including (from left to right) the wall, bracket/flange, transmitter, button, frame and screws;

FIGS. 21a and 21b are exploded and assembled elevation views of an alternate recess mounted transmitter of FIGS. 19a and 19b including (from left to right) the wall, bracket/flange, transmitter, button, frame and screws using a deeper flange to produce a narrower profile button/switch.

FIG. 22 is a plan view of a single function toggle switch as in FIG. 19 in a wall mounting plate adjacent one conventional wired switch as in FIG. 17;

FIG. 23 is a plan view of a single function toggle switch as in FIG. 19 in a wall mounting plate adjacent two conventional wired switches as in FIG. 17;

FIG. 24 is a plan view of a single function toggle switch as in FIG. 19a-19b in a wall mounting plate adjacent two multifunction wall switches as in FIGS. 18 and 11;

FIG. 25 is a plan view of three multifunction wall switches as in FIGS. 18 and 11 mounted adjacently in a wall mounting plate;

FIG. 26 is a plan view of a multifunction wall switch as in FIGS. 18 and 11 in a wall mounting plate adjacent one conventional wired switch as in FIG. 17;

FIG. 27 is a plan view of a multifunction wall switch as in FIGS. 18 and 11 in a wall mounting plate adjacent two conventional wired switches as in FIG. 17;

FIG. 28 is a plan view of a multifunction wall switch as in FIGS. 18 and 11 in a wall mounting plate adjacent three conventional wired switches as in FIG. 17;

FIG. 29 is a plan view of a multifunction wall switch as in FIGS. 18 and 11 in a wall mounting plate adjacent a conventional wired switch as in FIG. 17, and a conventional small toggle wall switch and a conventional push-button rotary wall dimmer switch;

FIG. 30 is a block diagram showing the components of a circuit for using the electrical signal generated by the device of FIGS. 4-8, and 22-29;

FIG. 31 is a block diagram showing the components of an alternate circuit for using the electrical signal generated by the device of FIGS. 4-8 and 22-29;

FIG. 32 is a block diagram showing the components of an alternate circuit for using the electrical signal generated by the device of FIGS. 4-8 and 22-29 incorporating a rechargeable battery and a transceiver;

FIG. 33 is a detailed circuit diagram of the circuits in FIGS. 30-32;

FIG. 34 is a detailed circuit diagram of the circuit in FIG. 33; and

FIG. 35 is a detailed circuit diagram of an alternate circuit in FIG. 33.

### DESCRIPTION OF THE PREFERRED EMBODIMENT

Electroactive Generator

Piezoelectric and electrostrictive materials (generally called “electroactive” devices herein) develop an electric field when placed under stress or strain. The electric field developed by a piezoelectric or electrostrictive material is a function of the applied force and displacement causing the mechanical stress or strain. Conversely, electroactive devices undergo dimensional changes in an applied electric field. The dimensional change (i.e., expansion or contraction) of an electroactive element is a function of the applied electric field. Electroactive devices are commonly used as drivers, or “actuators” due to their propensity to deform under such electric fields. These electroactive devices when used as transducers or generators also have varying capacities to generate an electric field in response to a deformation caused by an applied force. In such cases they behave as electrical generators.

Electroactive devices include direct and indirect mode actuators, which typically make use of a change in the dimensions of the material to achieve a displacement, but in the present invention are preferably used as electromechanical generators. Direct mode actuators typically include a piezoelectric or electrostrictive ceramic plate (or stack of plates) sandwiched between a pair of electrodes formed on its major surfaces. The devices generally have a sufficiently large piezoelectric and/or electrostrictive coefficient to produce the desired strain in the ceramic plate. However, direct mode actuators suffer from the disadvantage of only being able to achieve a very small displacement (strain), which is, at best, only a few tenths of a percent. Conversely, direct mode generator-actuators require application of a high amount of force to piezoelectrically generate a pulsed momentary electrical signal of sufficient magnitude to activate a latching relay.

Indirect mode actuators are known to exhibit greater displacement and strain than is achievable with direct mode actuators by achieving strain amplification via external structures. An example of an indirect mode actuator is a flextensional transducer. Flextensional transducers are composite structures composed of a piezoelectric ceramic element and a metallic shell, stressed plastic, fiberglass, or similar structures. The actuator movement of conventional flextensional devices commonly occurs as a result of expansion in the piezoelectric material which mechanically couples to an amplified contraction of the device in the transverse direction. In operation, they can exhibit several orders of magnitude greater strain and displacement than can be produced by direct mode actuators.

The magnitude of achievable deflection (transverse bending) of indirect mode actuators can be increased by constructing them either as “unimorph” or “bimorph” flextensional actuators. A typical unimorph is a concave structure composed of a single piezoelectric element externally bonded to a flexible metal foil, and which results in axial buckling (deflection normal to the plane of the electroactive element) when electrically energized. Common unimorphs can exhibit transverse bending as high as 10%, i.e., a deflection normal to the plane of the element equal to 10% of the length of the actuator. A conventional bimorph device includes an intermediate flexible metal foil sandwiched between two piezoelectric elements. Electrodes are bonded to each of the major surfaces of the ceramic elements and the metal foil is bonded to the inner two electrodes. Bimorphs exhibit more displacement than comparable unimorphs because under the applied voltage, one ceramic element will contract while the other expands. Bimorphs can exhibit transverse bending of up to 20% of the Bimorph length.

For certain applications, asymmetrically stress biased electroactive devices have been proposed in order to increase the transverse bending of the electroactive generator, and therefore increase the electrical output in the electroactive material. In such devices, (which include, for example, “Rainbow” actuators (as disclosed in U.S. Pat. No. 5,471,721), and other flextensional actuators) the asymmetric stress biasing produces a curved structure, typically having two major surfaces, one of which is concave and the other which is convex.

Thus, various constructions of flextensional piezoelectric and ferroelectric generators may be used including: indirect mode actuators (such as “moonies” and, CYMBAL); bending actuators (such as unimorph, bimorph, multimorph or monomorph devices); prestressed actuators (such as “THUNDER” and rainbow” actuators as disclosed in U.S. Pat. No. 5,471,721); and multilayer actuators such as stacked actuators; and polymer piezofilms such as PVDF. Many other electromechanical devices exist and are contemplated to function similarly to power a transceiver circuit in the invention.

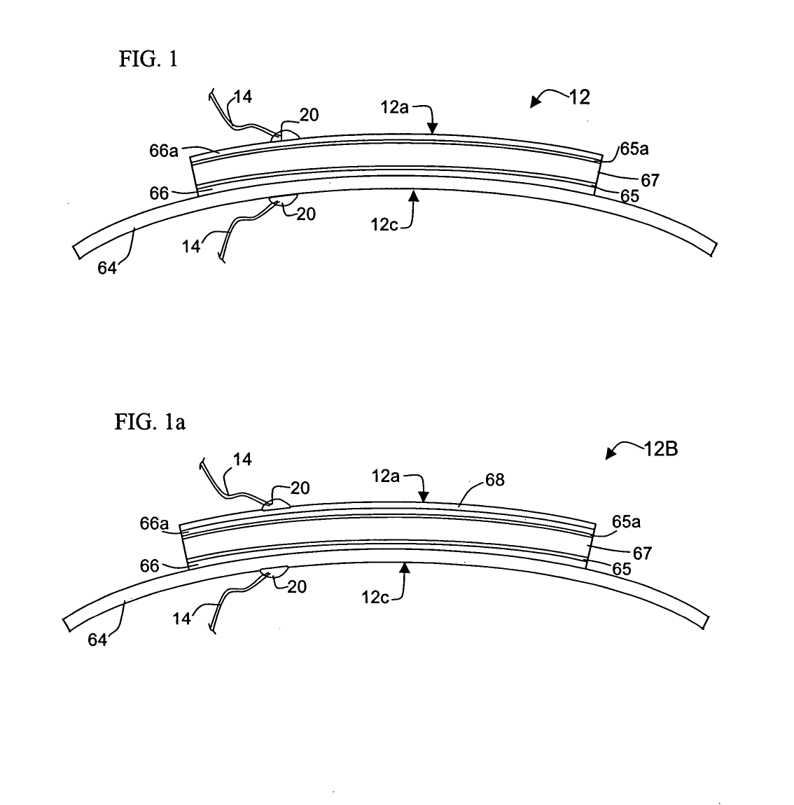

Referring to FIG. 1: The electroactive generator preferably comprises a prestressed unimorph device called “THUNDER”, which has improved displacement and load capabilities, as disclosed in U.S. Pat. No. 5,632,841. THUNDER (which is an acronym for THin layer composite UNimorph ferroelectric Driver and sEnsoR), is a unimorph device in which a pre-stress layer is bonded to a thin piezoelectric ceramic wafer at high temperature. During the cooling down of the composite structure, asymmetrical stress biases the ceramic wafer due to the difference in thermal contraction rates of the pre-stress layer and the ceramic layer. A THUNDER element comprises a piezoelectric ceramic layer bonded with an adhesive (preferably an imide) to a metal (preferably stainless steel) substrate. The substrate, ceramic and adhesive are heated until the adhesive melts and they are subsequently cooled. During cooling as the adhesive solidifies the adhesive and substrate thermally contracts more than the ceramic, which compressively stresses the ceramic. Using a single substrate, or two substrates with differing thermal and mechanical characteristics, the actuator assumes its normally arcuate shape. The transducer or electroactive generator may also be normally flat rather than arcuate, by applying equal amounts of prestress to each side of the piezoelectric element, as dictated by the thermal and mechanical characteristics of the substrates bonded to each face of the piezo-element.

The THUNDER element 12 is as a composite structure, the construction of which is illustrated in FIG. 1. Each THUNDER element 12 is constructed with an electroactive member preferably comprising a piezoelectric ceramic layer 67 of PZT which is electroplated 65 and 65a on its two opposing faces. A pre-stress layer 64, preferably comprising spring steel, stainless steel, beryllium alloy, aluminum or other flexible substrate (such as metal, fiberglass, carbon fiber, KEVLAR™, composites or plastic), is adhered to the electroplated 65 surface on one side of the ceramic layer 67 by a first adhesive layer 66. In the simplest embodiment, the adhesive layer 66 acts as a prestress layer. The first adhesive layer 66 is preferably LaRC™-SI material, as developed by NASA-Langley Research Center and disclosed in U.S. Pat. No. 5,639,850. A second adhesive layer 66a, also preferably comprising LaRC-SI material, is adhered to the opposite side of the ceramic layer 67. During manufacture of the THUNDER element 12 the ceramic layer 67, the adhesive layer(s) 66 and 66a and the pre-stress layer 64 are simultaneously heated to a temperature above the melting point of the adhesive material. In practice the various layers composing the THUNDER element (namely the ceramic layer 67, the adhesive layers 66 and 66a and the pre-stress layer 64) are typically placed inside of an autoclave, heated platen press or a convection oven as a composite structure, and slowly heated under pressure by convection until all the layers of the structure reach a temperature which is above the melting point of the adhesive 66 material but below the Curie temperature of the ceramic layer 67. Because the composite structure is typically convectively heated at a slow rate, all of the layers tend to be at approximately the same temperature. In any event, because an adhesive layer 66 is typically located between two other layers (i.e. between the ceramic layer 67 and the pre-stress layer 64), the ceramic layer 67 and the pre-stress layer 64 are usually very close to the same temperature and are at least as hot as the adhesive layers 66 and 66a during the heating step of the process. The THUNDER element 12 is then allowed to cool.

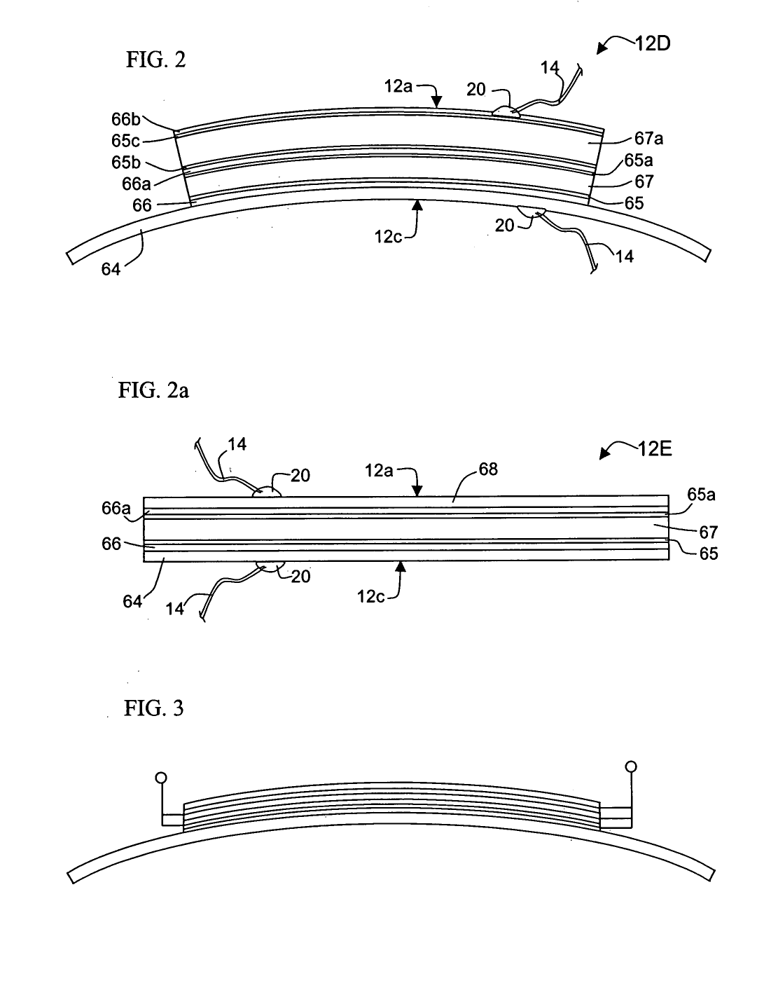

During the cooling step of the process (i.e. after the adhesive layers 66 and 66a have re-solidified) the ceramic layer 67 becomes compressively stressed by the adhesive layers 66 and 66a and pre-stress layer 64 due to the higher coefficient of thermal contraction of the materials of the adhesive layers 66 and 66a and the pre-stress layer 64 than for the material of the ceramic layer 67. Also, due to the greater thermal contraction of the laminate materials (e.g. the first pre-stress layer 64 and the first adhesive layer 66) on one side of the ceramic layer 67 relative to the thermal contraction of the laminate material(s) (e.g. the second adhesive layer 66a) on the other side of the ceramic layer 67, the ceramic layer deforms in an arcuate shape having a normally convex face 12a and a normally concave face 12c, as illustrated in FIGS. 1 and 2.

Referring to FIG. 1a: One or more additional pre-stressing layer(s) may be similarly adhered to either or both sides of the ceramic layer 67 in order, for example, to increase the stress in the ceramic layer 67 or to strengthen the THUNDER element 12B. In a preferred embodiment of the invention, a second prestress layer 68 is placed on the concave face 12a of the THUNDER element 12B having the second adhesive layer 66a and is similarly heated and cooled. Preferably the second prestress layer 68 comprises a layer of conductive metal. More preferably the second prestress layer 68 comprises a thin foil (relatively thinner than the first prestress layer 64) comprising aluminum or other conductive metal. During the cooling step of the process (i.e. after the adhesive layers 66 and 66a have re-solidified) the ceramic layer 67 similarly becomes compressively stressed by the adhesive layers 66 and 66a and pre-stress layers 64 and 68 due to the higher coefficient of thermal contraction of the materials of the adhesive layers 66 and 66a and the pre-stress layers 64 and 68 than for the material of the ceramic layer 67. Also, due to the greater thermal contraction of the laminate materials (e.g. the first pre-stress layer 64 and the first adhesive layer 66) on one side of the ceramic layer 67 relative to the thermal contraction of the laminate material(s) (e.g. the second adhesive layer 66a and the second prestress layer 68) on the other side of the ceramic layer 67, the ceramic layer 67 deforms into an arcuate shape having a normally convex face 12a and a normally concave face 12c, as illustrated in FIG. 1a.

Alternately, the second prestress layer 68 may comprise the same material as is used in the first prestress layer 64, or a material with substantially the same mechanical strain characteristics. Using two prestress layers 64, 68 having similar mechanical strain characteristics ensures that, upon cooling, the thermal contraction of the laminate materials (e.g. the first pre-stress layer 64 and the first adhesive layer 66,) on one side of the ceramic layer 67 is substantially equal to the thermal contraction of the laminate materials (e.g. the second adhesive layer 66a and the second prestress layer 68) on the other side of the ceramic layer 67, and the ceramic layer 67 and the transducer 12 remain substantially flat, but still under a compressive stress.

Alternatively, the substrate comprising a separate prestress layer 64 may be eliminated and the adhesive layers 66 and 66a alone or in conjunction may apply the prestress to the ceramic layer 67. Alternatively, only the prestress layer(s) 64 and 68 and the adhesive layer(s) 66 and 66a may be heated and bonded to a ceramic layer 67, while the ceramic layer 67 is at a lower temperature, in order to induce greater compressive stress into the ceramic layer 67 when cooling the transducer 12.

Referring now to FIG. 2: Yet another alternate THUNDER generator element 12D includes a composite piezoelectric ceramic layer 69 that comprises multiple thin layers 69a and 69b of PZT which are bonded to each other or cofired together. In the mechanically bonded embodiment of FIG. 2, two layers 69a and 69b, or more (not shown) my be used in this composite structure 12D. Each layer 69a and 69b comprises a thin layer of piezoelectric material, with a thickness preferably on the order of about 1 mil. Each thin layer 69a and 69b is electroplated 65 and 65a, and 65b and 65c on each major face respectively. The individual layers 69a and 69b are then bonded to each other with an adhesive layer 66b, using an adhesive such as LaRC-SI. Alternatively, and most preferably, the thin layers 69a and 69b may be bonded to each other by cofiring the thin sheets of piezoelectric material together. As few as two layers 69a and 69b, but preferably at least four thin sheets of piezoelectric material may be bonded/cofired together. The composite piezoelectric ceramic layer 69 may then be bonded to prestress layer(s) 64 with the adhesive layer(s) 66 and 66a, and heated and cooled as described above to make a modified THUNDER transducer 12D. By having multiple thinner layers 69a and 69b of piezoelectric material in a modified transducer 12D, the composite ceramic layer generates a lower voltage and higher current as compared to the high voltage and low current generated by a THUNDER transducer 12 having only a single thicker ceramic layer 67. Additionally, a second prestress layer may be used comprise the same material as is used in the first prestress layer 64, or a material with substantially the same mechanical strain characteristics as described above, so that the composite piezoelectric ceramic layer 69 and the transducer 12D remain substantially flat, but still under a compressive stress.

Referring now to FIG. 2b: Yet another alternate THUNDER generator element 12E includes another composite piezoelectric ceramic layer 169 that comprises multiple thin layers 169a-f of PZT which are cofired together. In the cofired embodiment of FIG. 2b, two or more layers 169a-f, and preferably at least four layers, are used in this composite structure 12E. Each layer 169a-f comprises a thin layer of piezoelectric material, with a thickness preferably on the order of about 1 mil, which are manufactured using thin tape casting for example. Each thin layer 169a-f placed adjacent each other with electrode material between each successive layer. The electrode material may include metallizations, screen printed, electro-deposited, sputtered, and/or vapor deposited conductive materials. The individual layers 169a-f and internal electrodes are then bonded to each other by cofiring the composite multi-layer ceramic element 169. The individual layers 169a-f are then poled in alternating directions in the thickness direction. This is accomplished by connecting high voltage electrical connections to the electrodes, wherein positive connections are connected to alternate electrodes, and ground connections are connected to the remaining internal electrodes. This provides an alternating up-down polarization of the layers 169a-f in the thickness direction. This allows all the individual ceramic layers 169a-f to be connected in parallel. The composite piezoelectric ceramic layer 169 may then be bonded to prestress layer(s) 64 with the adhesive layer(s) 66 and 66a, and heated and cooled as described above to make a modified THUNDER transducer 12D.

Referring again to FIGS. 2, 2a and 3: By having multiple thinner layers 69a and 69b (or 169a-f) of piezoelectric material in a modified transducer 12D-F, the composite ceramic layer generates a lower voltage and higher current as compared to the high voltage and low current generated by a THUNDER transducer 12 having only a single thicker ceramic layer 67. This is because with multiple thin paralleled layers the output capacitance is increased, which decreases the output impedance, which pr9ovides better impedance matching with the electronic circuitry connected to the THUNDER element. Also, since the individual layers of the composite element are th8inner, the output voltage can be reduced to reach a voltage which is closer to the operating voltage of the electronic circuitry (in a range of 3.3V-10.0V) which provides less waste in the regulation of the voltage and better matching to the desired operating voltages of the circuit. Thus the multilayer element (bonded or cofired) improves impedance matching with the connected electronic circuitry and improves the efficiency of the mechanical to electrical conversion of the element.

A flexible insulator may be used to coat the convex face 12a of the transducer 12. This insulative coating helps prevent unintentional discharge of the piezoelectric element through inadvertent contact with another conductor, liquid or human contact. The coating also makes the ceramic element more durable and resistant to cracking or damage from impact. Since LaRC-SI is a dielectric, the adhesive layer 67a on the convex face 12a of the transducer 12 may act as the insulative layer. Alternately, the insulative layer may comprise a plastic, TEFLON or other durable coating.

Electrical energy may be recovered from or introduced to the generator element 12 (or 12D) by a pair of electrical wires 14. Each electrical wire 14 is attached at one end to opposite sides of the generator element 12. The wires 14 may be connected directly to the electroplated 65 and 65a faces of the ceramic layer 67, or they may alternatively be connected to the pre-stress layer(s) 64 and or 68. The wires 14 are connected using, for example, conductive adhesive, or solder 20, but most preferably a conductive tape, such as a copper foil tape adhesively placed on the faces of the electroactive generator element, thus avoiding the soldering or gluing of the conductor. As discussed above, the pre-stress layer 64 is preferably adhered to the ceramic layer 67 by LaRC-SI material, which is a dielectric. When the wires 14 are connected to the pre-stress layer(s) 64 and/or 68, it is desirable to roughen a face of the pre-stress layer 68, so that the pre-stress layer 68 intermittently penetrates the respective adhesive layers 66 and 66a, and makes electrical contact with the respective electroplated 65 and 65a faces of the ceramic layer 67. Alternatively, the Larc-SI adhesive layer 66 may have a conductive material, such as Nickel or aluminum particles, used as a filler in the adhesive and to maintain electrical contact between the prestress layer and the electroplated faces of the ceramic layer(s). The opposite end of each electrical wire 14 is preferably connected to an electric pulse modification circuit 10.

Prestressed flextensional transducers 12 are desirable due to their durability and their relatively large displacement, and concomitant relatively high voltage that such transducers are capable of developing when deflected by an external force. The present invention however may be practiced with any electroactive element having the properties and characteristics herein described, i.e., the ability to generate a voltage in response to a deformation of the device. For example, the invention may be practiced using magnetostrictive or ferroelectric devices. The transducers also need not be normally arcuate, but may also include transducers that are normally flat, and may further include stacked piezoelectric elements.

In operation, when a force indicated by arrow 16 is applied to the convex face 12a or an edge 121 of the transducer 12, the force deforms the electroactive layer 67. The force may be applied to the transducer 12 by any appropriate means such as by application of manual pressure directly to the transducer, or by other mechanical means. Preferably, the force is applied by a mechanical switch (e.g., a plunger, striker, toggle or roller switch) capable of developing a mechanical impulse for application to and removal from the transducer 12. The mechanical impulse (or removal thereof) is of sufficient force to cause the transducer 12 to deform quickly and accelerate over a distance (approximately 10 mm), and oscillate between deflected positions about the undeflected position, which generates an electrical signal of sufficient magnitude to activate downstream circuit components for operation of an electromechanical latching relay, or generation of an RF transmission to activate a receiver which operates the electromechanical latching relay.

As previously mentioned, the applied force causes the piezoelectric transducer 12 to deform. By virtue of the piezoelectric effect, the deformation of the piezoelectric element 67 generates an instantaneous voltage between the faces 12a and 12c of the transducer 12, which produces a pulse of electrical energy. Furthermore, when the force is removed from the piezoelectric transducer 12, the transducer 12 recovers its original arcuate shape. This is because the bending of the substrate (and attached layers) stores mechanical (spring) energy which is released upon removal of the force. Additionally, the substrate or prestress layers 64 and 68 to which the ceramic 67 is bonded exert a compressive force on the ceramic 67, and the transducer 12 thus has an additional restoring force that causes the transducer 12 to return to its undeformed neutral state. On the recovery stroke of the transducer 12, the ceramic 67 returns to its undeformed state and thereby produces another electrical pulse of opposite polarity. The downward (applied) or upward (recovery) strokes cause a force over a distance that is of sufficient magnitude to create the desired electrical pulse. The duration of the recovery stroke, and therefore the duration of the pulse produced, is preferably in the range of 50-100 milliseconds, depending on the mechanical properties of the transducer, including its natural frequency of vibration.

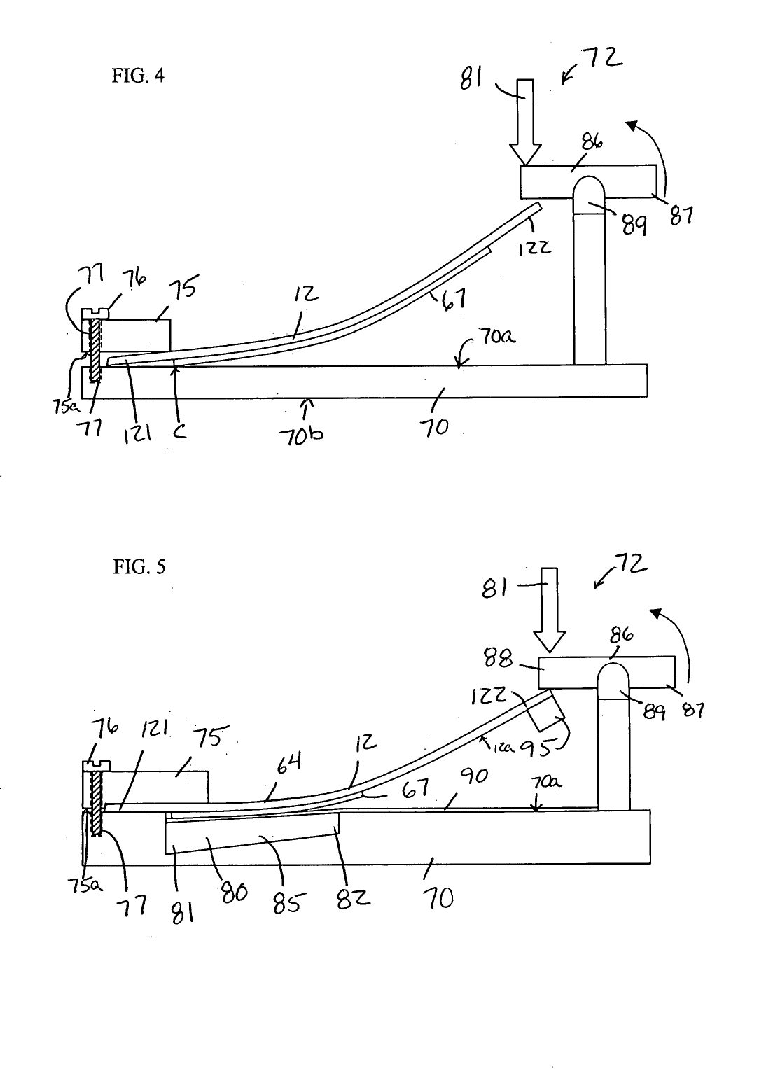

Referring to FIG. 4: In the preferred embodiment of the invention, the transducer 12 is clamped at one end 121 and the mechanical impulse is applied to the edge on the free end 122, i.e., at the end opposite to the clamped end 121 of the transducer 12. By applying the force to the edge on the free end 122 of the transducer 12 and releasing it, the actuator oscillates between the release position, to another position past the undeformed position, and then dampedly oscillates between the deformed positions returning to the undeformed position, by virtue of the substrates (spring steel) restoring force. Therefore, the electrical pulse that is generated upon removal of the force is an oscillating wave (rather than a single pulse as with the prior actuating means disclosed above).

Referring again to FIG. 4: FIG. 4 illustrates one embodiment of a device for generating an oscillating electrical signal by application of mechanical force to an end 122 of the transducer 12. This device comprises a transducer 12 mounted between a base plate 70 and a clamping member 75 as well as a deflector assembly 72. The base plate 70 is preferably of substantially the same shape (in plan view) as the transducer 12 attached thereon, and most preferably rectangular. One end 121 of the piezoelectric transducer 12 is held in place between the clamping member 75 and the upper surface 70a of a base plate 70, preferably on one end thereof. The clamping member 75 comprises a plate or block having a lower surface 75a designed to mate with the upper surface 70a of the base plate 70 with the transducer 12 therebetween. The device also has means for urging 76 the mating surface 75a of the clamping block towards the upper surface 70a of the base plate 70. This allows the lower surface 75a of the clamping plate 75 to be substantially rigidly coupled to the upper surface 70a of the base plate 70, preferably towards one side of the switch plate 70. The means for urging 76 together the mating surfaces 70a and 75a of the base plate 70 and clamping plate 75 may comprise screws, clamping jaws or springs or the like. Most preferably the urging means 76 comprises at least one screw 76 passing through the clamping member 75 and into a screw hole 77 in the upper surface 70a of the base plate 70.

One end 121 of a transducer 12 is placed between the mating surfaces 70a and 75a of the base and clamping plates 70 and 75. The mating surfaces 70a and 75a are then urged towards each other with the screw 76 to rigidly hold the end 121 of the transducer 12 in place between the base and clamping plates 70 and 75 with the opposite end 122 of the transducer 12 free to be moved by a mechanical impulse applied manually or preferably by a deflector assembly 72. The transducer 12 may further be aligned and securely retained between the base plate 70 and clamping plate 75 by means of one or more pins (not shown) on the base plate 70 and/or clamping plate 75 and holes (not shown) in the end 121 of the transducer 12.

Referring now to FIG. 5: In the preferred embodiment of the invention the surfaces 70a and 75a of the base and clamping plate 70 and 75 are designed to best distribute pressure evenly along the end 121 of the transducer 12 therebetween. To this end the upper surface 70a of the base plate 70 contacting the end 121 of the transducer 12 is preferably substantially flat and lower surface 75a of the clamping member 75 preferably has a recess 74 therein which accommodates insertion of the transducer end 121 therein. Preferably the depth of the recess 74 is equal to half the thickness of the transducer substrate 64, but may be as deep as the substrate thickness. Thus, the end 121 of the transducer 12 may be placed between the recess 74 and the upper surface 70a of the base plate 70 and secured therebetween by the screw 76. Alternatively, either or both of the mating surfaces 70a and 75a of the base and clamping plates 70 and 75 may have a recess therein to accommodate insertion and retention of the end 121 of the transducer 12 therebetween. The portion of the bottom surface 75a of the clamping member 75 beyond the recess 74 has no contact with the transducer 12, and is that portion through which the screw 76 passes. This portion of the bottom surface 75a may contact the upper surface 70a of the base plate 70, but most preferably there is a small gap (equal to the difference of the substrate thickness and the recess depth) between the lower surface 75a of the clamping member 75 and the top surface 70a of the base plate 70 when the transducer 12 is inserted therebetween. In yet another embodiment of the invention, the mating surfaces 70a and 75a of the base and clamping plates 70 and 75 may be adhesively bonded together (rather than screwed) with the end 121 of the transducer 12 sandwiched therebetween. In yet another alternative embodiment of the device, the clamping member 75 and base plate 70 may comprise a single molded structure having a central slot into which may be inserted one end 121 of the transducer 12.

The clamping assembly 75 holds the transducer 12 in place in its relaxed, i.e., undeformed state above the base plate 70 with the free end 122 of the transducer 12 in close proximity to a deflector 72 assembly. More specifically, the transducer 12 is preferably clamped between the mating surfaces 70a and 75a of the base and clamping plates 70 and 75 with the convex face 12a of the transducer 12 facing the base plate 70. Since the transducer 12 in its relaxed state is arcuate, the convex face 12a of the transducer 12 curves away from the upper surface 70a of the base plate 70 while approaching the free end 122 of the transducer 12. Mechanical force may then be applied to the free end 122 of the transducer 12 in order to deform the electroactive element 67 to develop an electrical signal.

Because of the composite, multi-layer construction of the transducer 12 it is important to ensure that the clamping member 75 not only holds the transducer 12 rigidly in place, but also that the transducer 12 is not damaged by the clamping member 75. In other words, the transducer 12, and more specifically the ceramic layer 67, should not be damaged by the clamping action of the clamping member 75 in a static mode, but especially in the dynamic state when applying a mechanical impulse to the transducer 12 with the plunger 72. For example, referring to FIG. 4, when a mechanical impulse is applied to the transducer 12 in the direction of arrow 81, the bottom corner of the ceramic (at point C) contacts the base plate 70 and is further pushed into the base plate, which may crack or otherwise damage the ceramic layer 67.

Referring again to FIG. 5: It has been found that the tolerances between the mating surfaces 75a and 70a of the clamping and base plates 75 and 70 are very narrow. It has also been found that application of a downward force (as indicated by arrow 81) to the free end 122 of the transducer 12 would cause the ceramic element 67 of the transducer 12 to contact the upper surface 70a of the base plate 70, thereby making more likely damage to the ceramic 67. Therefore, in the preferred embodiment of the invention, the base plate 70 has a recessed area 80 in its upper surface 70a which not only protects the electroactive element 67 from damage but also provides electrical contact to the convex face 12a of the transducer 12 so that the electrical signal developed by the transducer 12 may be applied to downstream circuit elements.

As can be seen in FIG. 5, one end 121 of the transducer 12 is placed between the surfaces 75a and 70a of the clamping and base plates 75 and 70 such that only the substrate 64 contacts both surface 75a and 70a. The clamping plate 75 preferably contacts the concave surface 12b of the transducer 12 along the substrate 64 up to approximately the edge of the ceramic layer 67 on the opposite face 12a of the transducer 12. The clamping member may however extend along the convex face 12c further than the edge C of the ceramic layer 67 in order to apply greater or more even pressure to the transducer 12 surfaces 12a and 12c between the clamping member 75 and base plate 70. The ceramic layer 67 which extends above the surface of the substrate 64 on the convex face 12a extends into the recessed area 80 of the switch plate 70. This prevents the ceramic layer 67 from contacting the upper surface 70a of the base plate 70, thereby reducing potential for damage to the ceramic layer 67.

The recess 80 is designed not only to prevent damage to the ceramic layer 67, but also to provide a surface along which electrical contact can be maintained with the electrode 68 on the convex face of the transducer 12. The recess 80 extends into the base plate 70 and has a variable depth, preferably being angled to accommodate the angle at which the convex face 12a of the transducer 12 rises from the recess 80 and above the top surface 70a of the base plate 70. More specifically, the recess 80 preferably has a deep end 81 and a shallow end 82 with its maximum depth at the deep end 81 beneath the clamping member 75 and substrate 12 just before where the ceramic layer 67 extends into the recess 80 at point C. The recess 80 then becomes shallower in the direction approaching the free end 122 of the transducer 12 until it reaches its minimum depth at the shallow end 82.

The recess 80 preferably contains a layer of compliant material 85 (preferably rubber, but alternately cork, urethane, silicone, felt or the like) along its lower surface which helps prevent the ceramic layer 67 from being damaged when the transducer 12 is deformed and the lower edge C of the ceramic layer 67 is pushed into the recess 80. Preferably the compliant layer 85 is of substantially uniform thickness along its length, the thickness of the compliant layer 85 being substantially equal to the depth of the recess 80 at the shallow end 82. The length of the compliant layer 85 is preferably slightly shorter than the length of the recess 80 to accommodate the deformation of the compliant layer 85 when the transducer 12 is pushed into the recess and compliant layer 85.

The compliant layer 85 preferably has a flexible electrode layer 90 overlying it to facilitate electrical contact with the aluminum layer 68 on the ceramic layer 67 on the convex face 12a of the transducer 12. More preferably, the electrode layer 90 comprises a layer of copper overlaying a layer of KAPTON film, as manufactured by E.I. du Pont de Nemours and Company, bonded to the compliant layer 85 with a layer of adhesive, preferably CIBA adhesive. The electrode layer 90 preferably extends completely across the compliant layer 85 from the deep end 81 to the shallow end 82 of the recess 80 and may continue as far as desired beyond the recess 80 along the top surface 70a of the base plate 70.

In the preferred embodiment of the invention, the end 121 of the transducer 12 is not only secured between the clamping plate 75 and the base plate 70, but the second prestress layer 68 covering the ceramic layer 67 of the transducer 12 is in constant contact with the electrode layer 90 in the recess 80 at all times, regardless of the position of the transducer 12 in its complete range of motion. To this end, the depth of the recess 80 (from the top surface 70a to the electrode 90) is at least equal to a preferably slightly less than the thickness of the laminate layers (adhesive layers 66, ceramic layer 67 and prestress layer 68) extending into the recess 80. The electrode layer is preferably adhered to either or both the aluminum layer 68 and the compliant layer 85, with a suitable adhesive, including for example, conductive adhesives.

An assembly was built having the following illustrative dimensions. The transducer 12 comprised a 1.59 by 1.79 inch spring steel substrate that was 8 mils thick. A 1-1.5 mil thick layer of adhesive having a nickel dust filler in a 1.51 inch square was placed one end of the substrate 0.02 inch from three sides of the substrate (leaving a 0.25 inch tab on one end 121 of the transducer 12). An 8-mil thick layer of PZT-5A type piezoelectric material in a 1.5 inch square was centered on the adhesive layer. A 1-mil thick layer of adhesive (with no metal filler) was placed in a 1.47 inch square centered on the PZT layer. Finally, a 1-mil thick layer of aluminum in a 1.46 inch square was centered on the adhesive layer. The tab 121 of the transducer 12 was placed in a recess in a clamping block 76 having a length of 0.375 inch and a depth of 4 mils. The base plate 70 had a 0.26 in long recess 80 where the deep end 81 of the recess had a depth of 20 mils and tapered evenly to a depth of 15 mils at the shallow end 82 of the recess 80. A rubber compliant layer 85 having a thickness of 15 mils and a length of 0.24 inches was placed in the recess 80. An electrode layer of 1 mil copper foil overlying 1 mil KAPTON tape was adhered to the rubber layer and extended beyond the recess 1.115 inches. The clamping member 75 was secured to the base plate 70 with a screw 76 and the aluminum second prestress layer of the transducer 12 contacted the electrode 90 in the recess 80 substantially tangentially (nearly parallel) to the angle the transducer 12 thereby maximizing the surface area of the electrical contact between the two.

As shown in FIG. 5, in an alternate embodiment of the invention, a weight 95 may be attached to the free end 122 of the transducer 12. The addition of the mass 95 to the free end 122 of the transducer 12, decreases the amount of damping of the oscillation and thereby increases the duration of oscillation of the transducer 12 when it was deflected and released. By having a longer duration and higher overall amplitude oscillation, the transducer 12 is capable of developing more electrical energy from its oscillation than an transducer 12 having no additional mass at its free end 122.

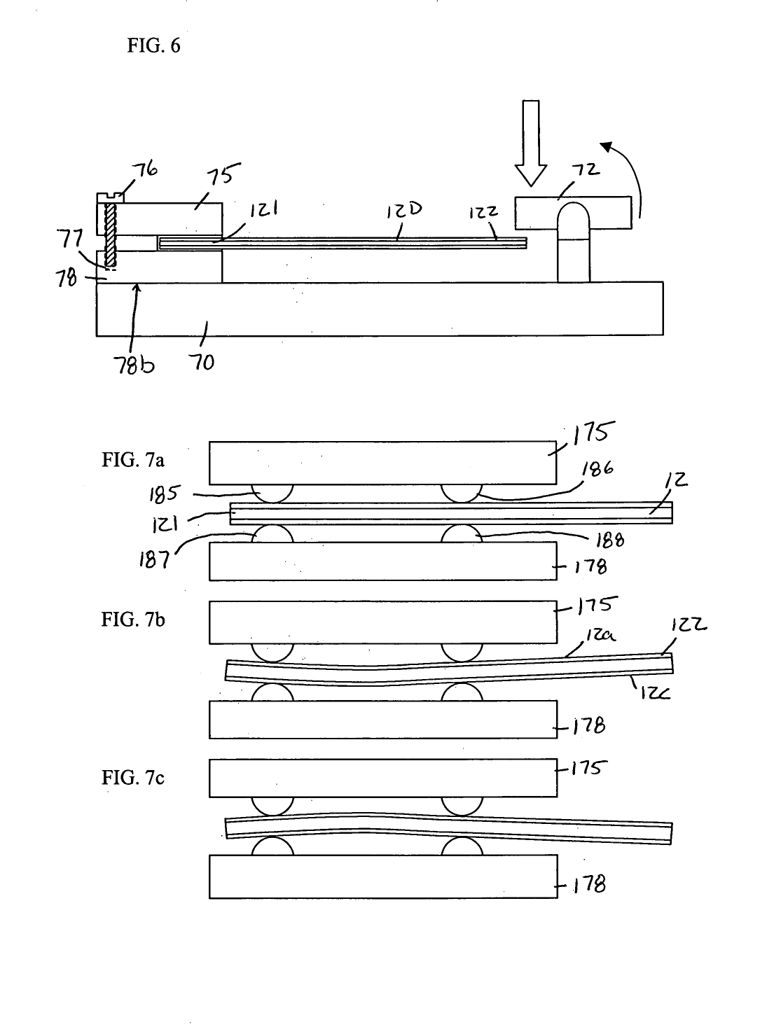

As shown in FIG. 6, in an alternate embodiment of the invention, a transducer 12, 12B, 12D may be mounted in a cantilever fashion. In FIG. 6, the transducer 12D pictured is that of FIG. 2A, but other transducers 12 or 12B may be similarly mounted. This mount also includes a base plate 70 and clamping plates 75, 78 for retaining the clamped end 121 of the transducer 12 therebetween, as well as deflector 72 mounted to the base plate 70 in proximity to the free end 122 of the transducer 12. The lower clamping plate 78 is rigidly connected to the base plate 70 at its lower surface 78b, and holds the transducer 12 on its top surface 78a above the top surface of the base plate 70, which allows the deflector 72 to deform the free end 122 of the transducer 12 up to the distance equal to the lower clamping plate's 78 thickness. The upper clamping plate 75 and lower clamping plate 78 hold the free end 121 of the transducer 12 therebetween through use of urging means, including the screw 76 and screw hole 77 pictured. Although the preferred embodiment of the invention uses a screw 76, other means for urging 76 the plates 75, 78 together may be used, such as clamping jaws, springs, clips, adhesives and the like.

Referring now to FIGS. 7a-7c: An alternate means for clamping the transducer 12 is shown, wherein each of the clamping plates 175, 177 has rounded projections thereon, for retaining the transducer 12, yet allowing some bending or the transducer 12 between the plates 175, 177, in order to distribute and reduce point bending forces on the retained portion 121 of the transducer 12. The clamping plates 175, 177 are urged together, preferably using one or more screws or bolts (not shown). In the preferred embodiment of the clamping plates 175, 177, the upper clamping plate 175 has two rounded projections 185, 186 thereon and the lower clamping plate 177 also has two rounded projections 187, 188 thereon. Each projection 185-188 is preferably shaped substantially like a half cylinder with the radius of the cylinder extending from the mating faces of the clamping plates 175, 177, and in the height dimension of the half cylinder are substantially perpendicular to the direction along which the transducer 12 extends from the plates 175, 177. The projections are constructed of a rigid, durable material such as metal or hard plastic. Each of the projections 185, 186 and 187, 188 are parallel to each other and equidistant, i.e., projections 185 and 186 are parallel and separated by the same distance as parallel projection 187 and 188. This facilitates placing the end 121 of the transducer 12 between the projections 185-188 so that the end 121 is retained between the plates 175, 177 along two parallel lines corresponding to the projections 185, 187 and 186, 188 on either side of the respective lines. The projections may alternately comprise multiple hemispherical projections, wherein each projection 185-188 comprises two or more hemispherical projections situated along the same axis as the semi-cylindrical projections 185-188.

As can be seen in FIGS. 7a-7c, when the free end 122 of transducer 12 is deflected as shown by arrows 191 and 192, the end 121 of the transducer 12 between the projections 185-188 is allowed to bend between and around the projections 185-188. Furthermore, the rounded shape of the projections 185-188 reduces point bending stresses in the transducer 12. This is because as the transducer 12 bends, the lines along which the projections 185, 187 and 186, 188 retain the transducer 12 actually shift slightly off of center (i.e., the apex of the projection) so that the transducer 12 is contacted at different points depending upon the amount the transducer 12 is deflected. This configuration allows the retained end 121 of the transducer 12 to bend without point stresses by distributing the stresses, thereby increasing the durability of the transducer 12, and also providing less attenuation to the desired oscillation of the transducer 12 due to the clamping.

Electrical contact to each of the faces 12a, 12c of the transducer 12 may be provided by use of wires 14 soldered to each face 12a, 12c. Alternately, conductive foil may be adhered to each face 12a, 12c of the transducer 12. As yet another alternative, by using metallic projections 185-188 on the clamping plates 175, 177, electrical contact with each of the faces 12a, 12c of the transducer 12 may be maintained, and conductors 14 may be attached to one or both of the projections 185, 186 and 187, 188 on each side 12a, 12c of the transducer 12, or alternately to the projections 185, 186 and 187, 188 via each of the plates 175, 177. By making electrical connections to conductive projections 185-188, bending and point stresses are eliminated from the conductors 14 electrically connected to each face 12a, 12c of the transducer 12 as it is bent.

Referring to FIGS. 4-6: As mentioned above, it is desirable to generate an electrical signal by deforming the transducer 12. Deformation of the transducer 12 may be accomplished by any suitable means such as manually or by mechanical deflection means such as a plunger, lever or the like. In FIGS. 6-8 a simple deflector 72 is mounted to the base plate 70 in proximity to the free end 122 of the transducer 12. This deflector assembly 72 includes a lever 86 having first and second ends 87 and 88. The lever is pivotably mounted between the two ends 87 and 88 to a fulcrum 89. By exerting a force on the first end 87 of the lever 86 in the direction of arrow 91, the lever pivots about the fulcrum 89 and applies a mechanical impulse in the direction of arrow 81 to the free end 122 of the transducer 12. Alternatively, the lever 86 may be moved opposite the direction of arrow 91 and the transducer 12 may thus be deflected in the direction opposite arrow 81.

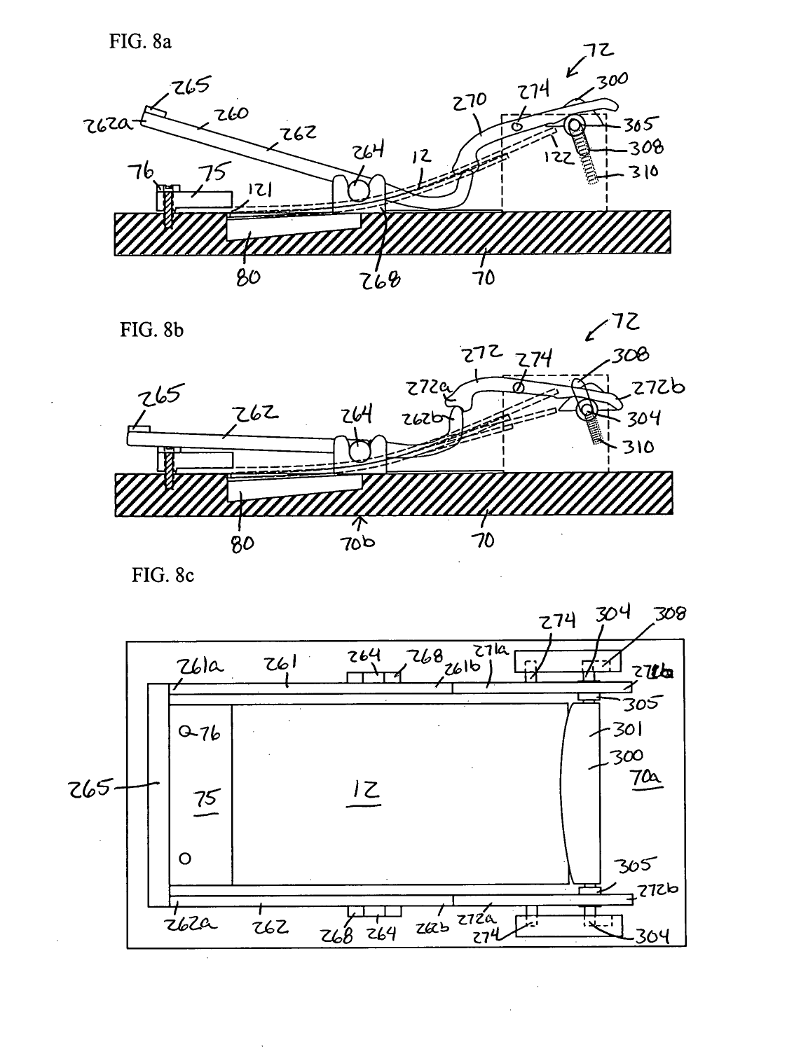

Referring now to FIGS. 8a-c: FIGS. 8a-c show the preferred embodiment of a base plate 70 with a deflector assembly 72 and containing the transducer 12. The transducer 12 is mounted as in FIG. 7, with one end 121 of the transducer 12 placed between the surfaces the clamping and base plates 75 and 70 such that the substrate 64 contacts both surfaces 75a and 70a. Alternately, the end 121 of the transducer 12 may be mounted between clamping plates 185, 187 as shown in FIGS. 7a-c. The ceramic layer 67 which extends above the surface of the substrate 64 on the convex face 12a extends into the recessed area 80 of the base plate 70. This prevents the ceramic layer 67 from contacting the upper surface 70a of the base plate 70, and cushions the ceramic layer 67 against the compliant layer 85 in the recess 80, thereby reducing potential for damage to the ceramic layer 67. A deflector assembly 72 is mounted on the base plate 70 above and to the sides of the transducer 12. This deflector assemble 72 has a lower profile than previously described deflector assemblies 72 by virtue of the use of two cooperating counter-rotating lever assembles 260, 270 and a plucker assembly 300.

Referring again to FIGS. 8a-c: The deflector assembly comprises a swing arm 260, which is essentially a first lever mounted above the clamped end 121 of the transducer 12 and tending towards the free end 122. The swing arm 260 preferably has two pivot arms 261 and 262 connected by a cross bar 265. The pivot arms 261 and 262 tend from above the clamped end 121 of the transducer 12 and tending towards the free end 122 of the transducer 12, along each side of the transducer 12 to prevent contact therebetween. A first end 261a, 262a of each pivot arm 261, 262 is connected to the two ends of a cross bar 265, which is situated above the clamping plate 75. Each pivot arm 261, 262, has a pin 264 extending outwardly from the transducer 12, located centrally on the pivot arms 261, 262. The pins are pivotably mounted within fulcrum clips 268, which allows the swing arm assembly 260 to pivot about the pins 264 and the fulcrum clips 268. The ends 261b, 262b of the pivot arms 261, 262 opposite the crossbar 265 are preferably upwardly curved to tend substantially vertically, or more preferably slightly off vertical and towards the free end 122 of the transducer 12 and rocker arm 270 assemblies. The curved ends 261,b, 262b of the pivot arms 261, 262 may alternately be C-shaped, i.e., first curve downwardly (towards the base plate 70, and then upwardly. To accommodate the downward curve of the pivot arm ends 261b, 262b, the base plate 70 may contain recesses (not shown) within which the curved ends 261b, 262b may housed.

Referring again to FIGS. 8a-c: The deflector assembly also comprises a rocker assembly 270, which is essentially a pair of second levers 271, 272 mounted above the free end 122 of the transducer 12 and tending towards and beyond the free end 122. The rocker assembly 270 preferably has two rocker arms 271 and 272 pivotably mounted to contact both the pivot arms 261, 262 and the plucker assembly 300. The rocker arms 271 and 272 tend from above the curved ends 261b, 262b of the pivot arms 261, 262 and tend towards and slightly beyond the free end 122 of the transducer 12, and along each side of the transducer 12 to prevent contact therebetween. Each of the rocker arms 271, 271 has a pin 274 thereon, extending outwardly from the transducer 12. Each of these pins 274 is pivotably mounted within a pivot hole 278 of the plucker housing 290. This allows each rocker arm 271, 272, to rotate about its respective pin 274 in response to a force on either end 271a, 272a, 271b, 272b of the rocker arm 271, 272. Each first end 271a, 272a of the rocker arms 271, 272 is in contact with the second ends 261b, 262b of the pivot arms 261, 262. When the crossbar 265 is depressed, the second ends 261b, 262b of the pivot arms 261, 262 move upwardly and contact the first ends 271a, 272a of the rocker arms 271, 272, causing the rocker arms 271, 272 to rotate about the rocker arm pins 274. This causes the second ends 271b, 272b of the rocker arms 271, 272 to be depressed.

Referring again to FIGS. 8a-c: The deflector assembly also comprises a plucker assembly 300, which is essentially a slidably mounted curved paddle situated above the free end 122 of the transducer 12. The plucker assembly 300 is in contact with the rocker assembly 270 and is adapted to side downwardly within a pair of grooves in response to a downward motion from the second ends 271b, 272b of the rocker arms 271, 272. More specifically, the plucker assembly 300 comprises a plucker paddle 301, situated above and in contact with the free end 122 of the transducer 12. Connected to each end 301a, 301b of the plucker paddle 301 is a roller 305, which is in contact with the rocker arms 271, 272. Tending outwardly from each roller 305 is a slide pin 304. The slide pins 304 are slidably mounted within slide grooves 308 in the plucker housings 290. The slide grooves 308 tend from a maximum vertical position and downwardly away from the free end 122 of the transducer 12 to a minimum position beyond the free end 122 of the transducer 12. Thus, when the plucker assembly 300 is moved downwardly, the slide pins 304 and slide grooves 308 cause the plucker paddle 301 to move simultaneously downward and away from the free end of 122 the transducer 12.

Thus, when the crossbar 265 is depressed, the second ends 261b, 262b of the pivot arms 261, 262 move upwardly and contact the first ends 271a, 272a of the rocker arms 271, 272, causing the rocker arms 271, 272 to rotate about the rocker arm pins 274. This causes the second ends 271b, 272b of the rocker arms 271, 272 to be depressed. As the second ends 271b, 272b of the rocker arms 271, 272 are depressed, they contact the rollers 305 with a downward force, and the plucker assembly 300 is guided by the slide pins 304 and slide grooves 308 to cause the plucker paddle 301 to move simultaneously downward and away from the free end of 122 the transducer 12. The minimum or lowest position of the plucker assembly is beyond the free end 122 of the transducer 12, and therefore, as the plucker paddle 301 moves downward and outward, the free end 122 of the transducer 12 is released by the plucker paddle 301. Thus as the plucker assembly is depressed, the free end 122 of the transducer 12 is depressed from its neutral position 291 to a deflected position 292 at which position the paddle 301 releases the free end 122 of the transducer 12. The free end 122 of the transducer 12 then oscillates between positions 291 and 292.

Referring now to FIG. 8c: The plucker paddle 301 preferably has an edge 301a that contacts the free end 122 of the transducer 12 that has a radius in both in the thickness dimension (i.e., vertically corresponding to the thickness of the transducer 12 edge) and the transverse dimension (i.e., horizontally corresponding to the length of the transducer 12 edge) in order to advantageously release the free end 122 very quickly, i.e., without dragging across the end 122 of the transducer 12, which slows its release. It has been found that the more quickly and cleanly you release the end 122 of the transducer 12 during a “pluck”, the greater the output. This increases output without increasing the required plucking force. To be precise, the energy developed by the piezoelectric element 67 has been found to be a function of the acceleration of the piezoelectric element 67, rather than the speed of the “pluck.” It is possible “pluck” very slowly, and get excellent performance, so long as the piezoelectric element 67 is released fully and completely and as nearly instantly as possible. To determine the desired shape of the tip 301a of the plucker paddle 301, several plucker paddles were designed and released very, very slowly, in attempting to get a quick “release” of the end 122 of the transducer 12. If the plucker paddle 301 did not have a radius on the tip, but instead had a rectangular shape, it was found that the end 301a of the plucker paddle 301 (the thickness dimension) actually “dragged” across the edge 122 of the transducer 12, slowing the release, and decreasing the electrical output. Thus, increasing the rate of “release” of the element's edge 122 improved the acceleration and the output. Thus, the radius of the tip 301a (in the thickness dimension) of the “plucker” paddle 301 contributes substantially to how quickly the transducer 12 edge 122 gets off the paddle. This has been shown to have a direct effect on electrical performance, because a smaller radius equates to a quicker “release” which equates to greater electrical output. If the paddle 301 is manufactured from sufficiently hard materials, or is hardened, the edge 301a of the paddle 301 can be made with an even smaller radius. The tip 301a of the plucking paddle 301 may be coated with a very hard material with low friction, thereby lowering the plucking resistance. This approach can prove to be useful in increasing the power output of a transducer 12 without increasing the required displacement or amount of bending, and may allow the generation of the same amount of energy with lower “button force” by the user of the device, as well as being useful in increasing wear resistance for applications requiring many hundreds of thousands of switch cycles.

The transducer 12 is typically is curved along its length, i.e., the longitudinal dimension and this curvature allows the element 12 to be bent or “plucked” substantially before it reaches a flattened state. The transducer 12 is also curved across its transverse dimension, i.e., the transverse dimension normal to the thickness and longitudinal dimensions. To ensure a quick “release”, the shape of the edge 301a of the plucking paddle 300 should generally match this transverse curve. The radius curvature of the transducer 12 in the transverse plane is approximately 6 inches, and therefore the same radius should be used for the curve edge 301a in the transverse plane of the paddle 301. Different sized transducers 12 will have higher or lower transverse radii of curvature, so regardless of the size of the transducer 12, the radius of curvature for the curved edge 301a in the transverse plane of the paddle 301 should substantially match the transverse curvature of the transducer 12.

Although both paddle 301 dimensions affect durability, and both dimensions affect performance, the tip radius has more of an effect on element 12 performance, while the transverse curve has a greater effect on the element's 12 substrate wear, and therefore is more of an influence on its life expectancy. This is because the transverse radius determines how much of the paddle 301 contacts the element 12. A greater contact area is equates with less wear and longer substrate life, i.e., durability. As stated above, by manufacturing the paddle 301 from sufficiently hard or hardened materials, the edge 301a of the paddle 301 can be made with very small radius. The tip 301a of the plucking paddle 301 may be coated with a very hard material with low friction, thereby lowering the plucking resistance. Hardened, low friction materials are useful in increasing the power output of a transducer 12 without increasing the required displacement or amount of bending, or allowing the generation of similar electrical energy output with lower “button force”, and increasing wear resistance.

Referring again to FIGS. 8a-c: In order to return the deflector assembly 72 to its normal elevated position, the levers 260, 270 and/or plucker assembly 300 are preferably spring loaded. More specifically, one or more springs 310 are located in contact with the deflector assembly 72, and are placed in compression or tension upon actuation of the assembly 72, which springs' 310 restoring force is used to return the deflector assembly 72 to its neutral position. As shown in FIGS. 8a-c, in the preferred embodiment of the invention, two springs 310 are located within cavities 320 in the plucker housings 290, below the pins 304. For simplicity of illustration, the springs 310 are shown as coiled springs 310, but are preferably leaf springs 310. Upon downward deflection of the crossbar 265 and thereby the pivot bar assembly 260 and rocker assembly 270, the pins 304 travel down the grooves 308 and compress the springs 310 in the cavities 320. Upon release of pressure from the crossbar 265, the springs 310 restore the pivot bar 260, rocker bars 270 and plucker 300 to their undeflected positions. While the springs 310 shown are in the housings 290, other placements of the springs 310 may also be desirable, including, for example: spring(s) 310 may be placed beneath the cross bar 265, on either side of the fulcrum 268 of the pivot bars 261, 262 or rocker arms 270; one or more rotational or clock springs 310 may be placed on the pins 264 of the pivot bars 261, 262, on the pins 274 of the rocker arms 271, 272, on the pivot bar fulcrums 268, or the rocker arm pin holes 278; springs 310 may be placed in the groove 308 or recess 320 above or below the plucker bar pins 304; one or more springs 310 may be attached to the plucker bar 301; and the opposing side of the spring 310 (not attached to the deflector assembly 72) may be attached to the base plate 70, the plucker housing 290, the fulcrum 268 or to another part of the deflector assembly 72 to restore it to its undeflected position.

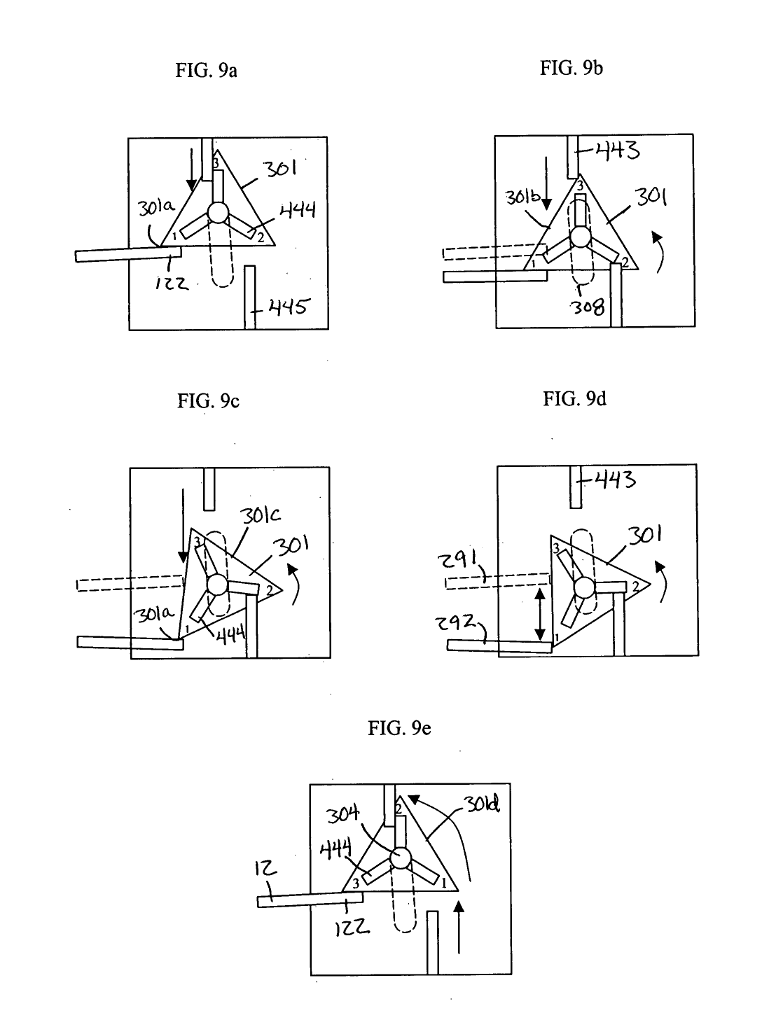

Referring now to FIGS. 9a-e: To facilitate efficient plucking and maximize vibration of the transducer 12, the plucker assembly is preferably configured so as to rotate during each actuation and to cock after each actuation. Specifically, with a triangularly shaped plucker paddle 301, any one of the three faces 301b, 301c, 301d of the plucker paddle 301 (having a substantially triangular cross-section) may engage the edge of the transducer. As the plucker paddle 301 moves downward and outward from the transducer edge, a rotation mechanism (including a pin 445 and radial ridge 444 as shown in the figures) causes the plucker paddle edge to rotate away from the transducer edge 122. As the plucker paddle rotates, it reaches a point where the transducer edge 122 is released. Since the plucker paddle 301 has rotated, it also does not interfere with the vibration of the transducer edge. When the downward force is removed from the plucker assembly, the spring loaded plucker paddle 301 is returned upward towards its starting position, and rotates until the radial ridge 444 contacts a rotational stop 443, so that the plucker paddle 301 is again is a position to engage the transducer edge.

Referring again to FIGS. 9a-e: More specifically, the plucker paddle 301 is shaped substantially like a triangular prism. In the center of each triangular face of the paddle is a pin 304 that travels along the groove 308 in the plucker housing. Each triangular face of the paddle also preferably has threes raised ridges 444 thereon extending from the center of the triangular face outwardly towards the edges of the triangular faces adjacent the flat paddle surfaces and most preferably towards each apex of the triangular faces. The plucker housings each have a vertical ridge or pin 443 against which the raised ridge rests when the plucker paddle is in its maximum position. This maintains the bottom surface of the plucker paddle (opposite the apex bisected by the raised ridge) in an essentially horizontal position above and/or against the edge of the transducer 12.

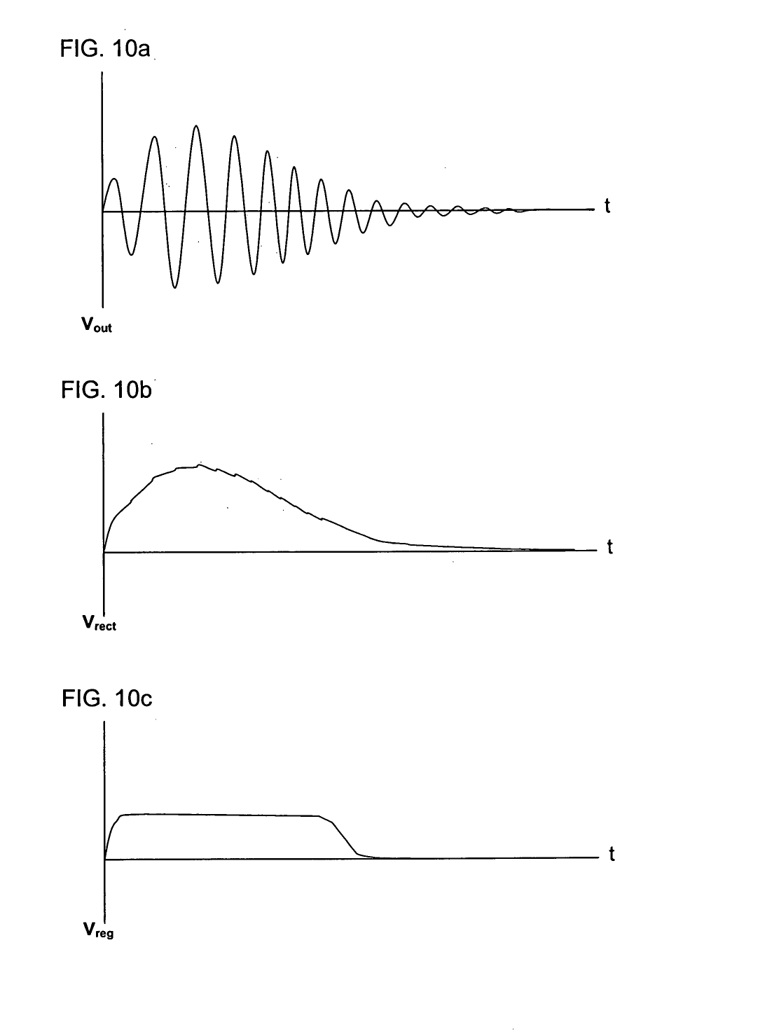

A force applied to the deflector assembly 72 described above causes the piezoelectric transducer 12 to deform from position 291 to position 292 and by virtue of the piezoelectric effect, the deformation of the piezoelectric element 67 generates an instantaneous voltage between the faces 12a and 12c of the transducer 12, which produces an electrical signal. Furthermore, when the force is removed from the piezoelectric transducer 12, i.e., when released by the plucker assembly 300 at position 292, the transducer 12 oscillates between positions 291 and 292 until it gradually returns to its original shape. As the transducer 12 oscillates, the ceramic layer 67 strains, becoming alternately more compressed and less compressed. The polarity of the voltage produced by the ceramic layer 67 depends on the direction of the strain, and therefore, the polarity of the voltage generated in compression is opposite to the polarity of the voltage generated in tension. Therefore, as the transducer 12 oscillates, the voltage produced by the ceramic element 67 oscillates between a positive and negative voltage for a duration of time. The duration of the oscillation, and therefore the duration of the oscillating electrical signal produced, is preferably in the range of 100-250 milliseconds, depending on the shape, mounting and amount of force applied to the transducer 12. The wave form of the oscillating voltage is illustrated in FIG. 10a.

When the end 122 of the transducer 12 is deflected and then released (either manually or using a deflector assembly 72 such as in FIGS. 4-9), the end 122 of the transducer 12, much like a diving board, oscillates back and forth between positions 291 and 292. This is because the substrate and prestress layer 64 and 68 to which the ceramic 67 is bonded exert a compressive force on the ceramic 67 thereby providing a restoring force. Therefore, the transducer 12 has a coefficient of elasticity or spring constant that causes the transducer 12 to return to its undeformed neutral state at position 291. The oscillation of the transducer 12 has the waveform of a damped harmonic oscillation, as is illustrated in FIG. 510a. In other words, the amplitude of the oscillation of the free end 122 of the transducer 12 is at its maximum immediately following (within a few oscillations after) the release of the mechanical impulse from the free end 122 of the transducer 12. As the transducer 12 continues to vibrate, the amplitude gradually decreases over time (approximately exponentially) until the transducer 12 is at rest in its neutral position 291, as shown in FIG. 10a.

The applied force, whether by manual or other mechanical deflection means 72 causes the piezoelectric transducer 12 to deform and by virtue of the piezoelectric effect, the deformation of the piezoelectric element 67 generates an instantaneous voltage between the faces 12a and 12c of the transducer 12, which produces an electrical signal. Furthermore, when the force is removed from the piezoelectric transducer 12, the transducer 12 oscillates between positions 291 and 292 until it gradually returns to its original shape. As the transducer 12 oscillates, the ceramic layer 67 strains, becoming alternately more compressed and less compressed. The polarity of the voltage produced by the ceramic layer 67 depends on the direction of the strain, and therefore, the polarity of the voltage generated in compression is opposite to the polarity of the voltage generated in tension. Therefore, as the transducer 12 oscillates, the voltage produced by the ceramic element 67 oscillates between a positive and negative voltage for a duration of time. The duration of the oscillation, and therefore the duration of the oscillating electrical signal produced, is preferably in the range of 100-500 milliseconds, depending on the shape, mounting and amount of force and number of plucks applied to the edge of the transducer 12.

The electrical signal generated by the transducer 12 is applied to downstream circuit elements via wires 14, and conductive foil, solder or conductive adhesive connected to the transducer 12. More specifically, a first wire 14 is connected to the electrode 90 which extends into the recess 80 and contacts the electrode 68 on the convex face 12a of the transducer 12 or to a foil adhered to the lower face 12a of the transducer 12. Preferably the wire 14 is attached to a conductive foil (not shown) adhered to the face 12a of the transducer 12 situated above the recess 80 and compliant layer 85. Alternately, the wire 14 is connected to the electrode 90 outside of the recess close to the end of the base plate 70 opposite the end having the clamping member 75. A second wire 14 is connected directly to the first prestress layer 64, i.e., the substrate 64 which acts as an electrode on the concave face 12c of the transducer 12.

Referring now to FIGS. 8a-c, 11-12 and 15: FIGS. 8a-c, 11-12 and 15 show an embodiment of a deflector assembly 72 containing the transducer 12 surrounded by a casing 200. The base plate 70 forms the base of a casing 200, which encloses the transducer 12. A button 210 is used to apply the force to the deflector assembly 72. The button 210 has a top surface 210a and four button sides 211, 212, 213 and 214 which extend substantially perpendicularly from the top surface 210a of the button 210. The button 210 is pivotably mounted via button hinge holes 215 in the sides 211, 213 of the button 210, which button hinge holes 215 are pivotably engaged with button hinge pins 216 which are fixedly mounted to a hinge base 217 on the base 70. When the button 210 is pushed, the button bottom surface 10b contacts the deflector assembly 72 thereby deforming/plucking the electroactive generator 72.

Surrounding the button 210 and mounted to the base plate 70 is a frame 250 having four walls 251, 252, 253 and 254 which extend perpendicularly from the top surface 70a of the base plate 70. There are preferably one or more clips along one or more of the wall 251, 252, 253 and 254 edges that engage with the edge of the bottom face 70b of the base 70. The frame walls 251, 252, 253 and 254 may also have a tapered or beveled portion 225 above the vertical portion of the walls (where the walls attach to and surround the underlying base 70) beveling inward towards the button 210 in the center of the frame 250. The frame 250 is removable from the base 70 and when removed allows access to other components, for example the hinge 216 pins to which the button 210 is attached, or to access screw holes 228 in the base 70, which may be used to attach the base 70 to a wall or other mounting surface.

In each embodiment of a self powered RF signal generator, the transducer 12, base 70 and associated transmission circuitry are enclosed in a case, such as described above having a base 200, a button 210 and a frame 250. The case may be made of a variety of materials including plastics and metal or combinations thereof. Most preferably, the case 200 comprises plastic. It has been discovered that the character of the RF signal radiated from the antenna 60 in the transmitter circuit 126 varies with the placement of the antenna 60 in relation to parts of the casing 200 as well as other obstructions placed in proximity to the antenna. To this end it is preferred that the antenna 60 be fixedly mounted to the base 70. Most preferably, the antenna 60 is affixed to the casing in a channel in the base 70/200. Furthermore, it is preferable that at least a portion of the base 70 be made of metal. Objects (i.e., in walls) to which the base 70 is mounted may cause interference with the signal radiated from the antenna 60. Therefore a portion of the base 70 is preferred to be metallic in order to shield the antenna from any interference. Most preferably, a metallic foil 400 is affixed to the back face 70b of the base 70 in proximity to the antenna 60 on the opposite face 70a of the base 70.

Switch Initiation System

Referring to FIGS. 6 and 7: The pulse of electrical energy is transmitted from the transducer or generator 12 via the electrical wires 14 connected to each of the transducer 12 to a switch or relay 90. The pulse of electrical energy is of sufficient magnitude to cause the switch/relay 90 to toggle from one position to another. Alternatively and preferably, the electrical pulse is first transmitted through a pulse modification circuit 10 in order to modify the character, i.e, current, voltage, frequency and/or pulse width of the electrical signal.

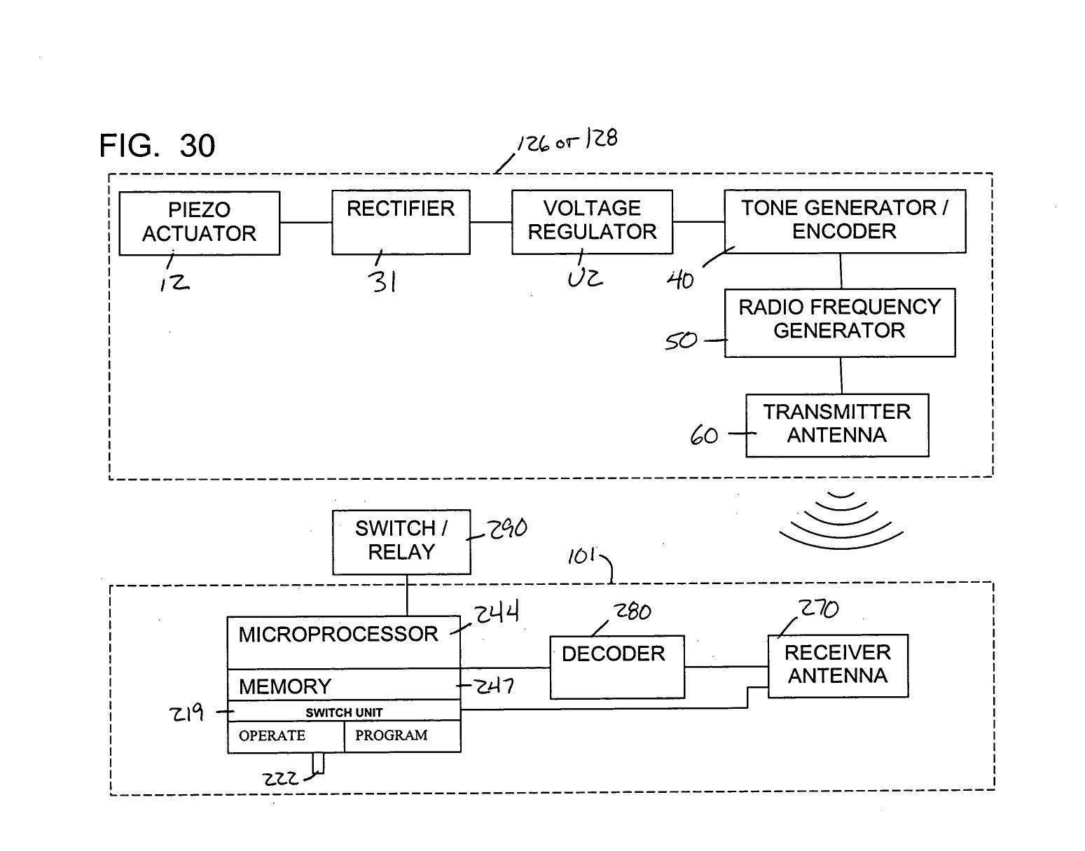

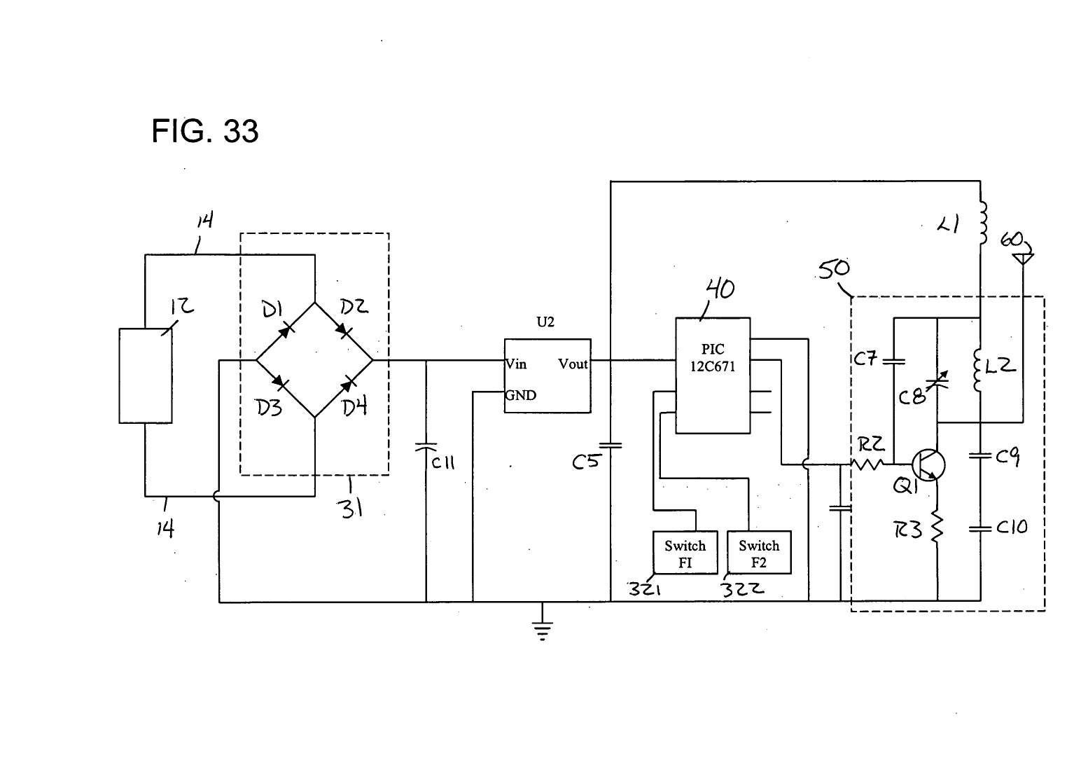

Referring to FIGS. 30-35, the transducer 12 is connected to circuit components downstream in order to generate an RF signal for actuation of a switch initiator. These circuit components include a rectifier 31, a voltage regulator U2, an encoder 40 (preferably comprising a peripheral interface controller (PIC) chip) as well as an RF generator 50 and antenna 60. FIG. 10b shows the waveform of the electrical signal of FIG. 10a after it has been rectified. FIG. 10c shows the waveform of the rectified electrical signal of FIG. 10b after it has been regulated to a substantially uniform voltage, preferably 3.3 VDC.

The transducer 12 is first connected to a rectifier 31. Preferably the rectifier 31 comprises a bridge rectifier 31 comprising four diodes D1, D2, D3 and D4 arranged to only allow positive voltages to pass. The first two diodes D1 and D2 are connected in series, i.e., the anode of D1 connected to the cathode of D2. The second two diodes D3 and D4 are connected in series, i.e., the anode of D3 connected to the cathode of D4. The anodes of diodes D2 and D4 are connected, and the cathodes of diodes D1 and D3 are connected, thereby forming a bridge rectifier. The rectifier is positively biased toward the D2-D4 junction and negatively biased toward the D1-D3 junction. One of the wires 14 of the transducer 12 is electrically connected between the junction of diodes D1 and D2, whereas the other wire 14 (connected to the opposite face of the transducer 12) is connected to the junction of diodes D3 and D4. The junction of diodes D1 and D3 are connected to ground. A capacitor C11 is preferably connected on one side to the D2-D4 junction and on the other side of the capacitor C11 to the D1-D3 junction in order to isolate the voltages at each side of the rectifier from each other. Therefore, any negative voltages applied to the D1-D2 junction or the D3-D4 junction will pass through diodes D1 or D3 respectively to ground. Positive voltages applied to the D1-D2 junction or the D3-D4 junction will pass through diodes D2 or D4 respectively to the D2-D4 junction. The rectified waveform is shown in FIG. 10b.

The circuit also comprises a voltage regulator U2, which controls magnitude of the input electrical signal downstream of the rectifier 31. The rectifier 31 is electrically connected to a voltage regulator U2 with the D2-D4 junction connected to the Vin pin of the voltage regulator U2 and with the D1-D3 junction connected to ground and the ground pin of the voltage regulator U2. The voltage regulator U2 comprises for example a LT1121 chip voltage regulator U2 with a 3.3 volts DC output. The output voltage waveform is shown in FIG. 10c and comprises a substantially uniform voltage signal of 3.3 volts having a duration of approximately 100-250 milliseconds, depending on the load applied to the transducer 12. The regulated waveform is shown in FIG. 10b. The output voltage signal from the voltage regulator (at the Vout pin) may then be transmitted via another conductor to the relay switch 290, in order to change the position of a relay switch 290 from one position to another. Preferably however, the output voltage is connected through an encoder 40 to an RF generation section 50 of the circuit.

The output of the voltage regulator U2 is preferably used to power an encoder 40 or tone generator comprising a peripheral interface controller (PIC) microcontroller that generates a pulsed tone. This pulsed tone modulates an RF generator section 50 which radiates an RF signal using a tuned loop antenna 60. The signal radiated by the loop antenna is intercepted by an RF receiver 270 and a decoder 280 which generates a relay pulse to activate the relay 290.

The output of the voltage regulator U2 is connected to a PIC microcontroller, which acts as an encoder 40 for the electrical output signal of the regulator U2. More specifically, the output conductor for the output voltage signal (nominally 3.3 volts) is connected to the input pin of the programmable encoder 40. Types of register-based PIC microcontrollers include the eight-pin PIC12C5XX and PIC12C67x, baseline PIC16C5X, midrange PIC16CXX and the high-end PIC17CXX/PIC18CXX. These controllers employ a modified Harvard, RISC architecture that support various-width instruction words. The datapaths are 8 bits wide, and the instruction widths are 12 bits wide for the PIC16C5X/PIC12C5XX, 14 bits wide for the PIC12C67X/PIC16CXX, and 16 bits wide for the PIC17CXX/PIC18CXX. PICMICROS are available with one-time programmable EPROM, flash and mask ROM. The PIC17CXX/PIC18CXX support external memory. The encoder 40 comprises for example a PIC model 12C671. The PIC12C6XX products feature a 14-bit instruction set, small package footprints, low operating voltage of 2.5 volts, interrupts handling, internal oscillator, on-board EEPROM data memory and a deeper stack. The PIC12C671 is a CMOS microcontroller programmable with 35 single word instructions and contains 1024×14 words of program memory, and 128 bytes of user RAM with 10 MHz maximum speed. The PIC12C671 features an 8-level deep hardware stack, 2 digital timers (8-bit TMR0 and a Watchdog timer), and a four-channel, 8-bit A/D converter.

The output of the PIC may include square, sine or saw waves or any of a variety of other programmable waveforms. Typically, the output of the encoder 40 is a series of binary square waveforms (pulses) oscillating between 0 and a positive voltage, preferably +3.3 VDC. The duration of each pulse (pulse width) is determined by the programming of the encoder 40 and the duration of the complete waveform is determined by the duration of output voltage pulse of the voltage regulator U2. A capacitor C5 is preferably connected on one end to the output of the voltage regulator U2, and on the other end to ground to act as a filter between the voltage regulator U2 and the encoder 40.

Thus, the use of an IC as a tone generator or encoder 40 allows the encoder 40 to be programmed with a variety of values. The encoder 40 is capable of generating one of many unique encoded signals by simply varying the programming for the output of the encoder 40. More specifically, the encoder 40 can generate one of a billion or more possible codes. It is also possible and desirable to have more than one encoder 40 included in the circuit in order to generate more than one code from one transducer 12 or transmitter. Alternately, any combination of multiple transducers and multiple pulse modification subcircuits may be used together to generate a variety of unique encoded signals. Alternately the encoder 40 may comprise one or more inverters forming a series circuit with a resistor and capacitor, the output of which is a square wave having a frequency determined by the RC constant of the encoder 40.

The DC output of the voltage regulator U2 and the coded output of the encoder 40 are connected to an RF generator 50. A capacitor C6 may preferably be connected on one end to the output of the encoder 40, and on the other end to ground to act as a filter between the encoder 40 and the RF generator 50. The RF generator 50 consists of tank circuit connected to the encoder 40 and voltage regulator U2 through both a bipolar junction transistor (BJT) Q1 and an RF choke L1. More specifically, the tank circuit consists of a resonant circuit comprising an inductor L2 and a capacitor C8 connected to each other at each of their respective ends (in parallel). Either the capacitor C8 or the inductor L2 or both may be tunable in order to adjust the frequency of the tank circuit. An inductor L1 acts as an RF choke, with one end of the inductor L1 connected to the output of the voltage regulator U2 and the opposite end of the inductor L1 connected to a first junction of the L2-C8 tank circuit. Preferably, the RF choke inductor L1 is an inductor with a diameter of approximately 0.125 inches and turns on the order of thirty and is connected on a loop of the tank circuit inductor L2. The second and opposite junction of the L2-C8 tank circuit is connected to the collector of BJT Q1. The base of the BJT Q1 is also connected through resistor R2 to the output side of the encoder 40. A capacitor C7 is connected to the base of a BJT Q1 and to the first junction of the tank circuit. Another capacitor C9 is connected in parallel with the collector and emitter of the BJT Q1. This capacitor C9 improves the feedback characteristics of the tank circuit. The emitter of the BJT Q1 is connected through a resistor R3 to ground. The emitter of the BJT Q1 is also connected to ground through capacitor C10 which is in parallel with the resistor R3. The capacitor C10 in parallel with the resistor R3 provides a more stable conduction path from the emitter at high frequencies.

The RF generator 50 works in conjunction with a tuned loop antenna 60. In the preferred embodiment, the inductor L2 of the tank circuit serves as the loop antenna 60. Alternatively, the inductor/loop antenna L2 comprises a single rectangular loop of copper wire having an additional smaller loop or jumper 61 connected to the rectangular loop L2. Adjustment of the shape and angle of the smaller loop 61 relative to the rectangular loop L2 is used to increase or decrease the apparent diameter of the inductor L2 and thus tunes the RF transmission frequency of the RF generator 50. In an alternate embodiment, a separate tuned antenna may be connected to the second junction of the tank circuit. Most preferably, the antenna 60 comprises a metallic wire whose length determines the radiated strength of the RF signal. This wire may have one or more “S-bends” to increase the overall length of the antenna. The antenna 60 is affixed, preferably with hot glue, to the top face 70 of the base 70. Attachment of the antenna 60 to the base affects the impedance of the antenna and the characteristics of the radiated signal. A metallic shield 500 may be provided adjacent the antenna 60 on the opposite side 70b of the base 70 to reduce interference with the RF signal.

In operation: The positive voltage output from the voltage regulator U2 is connected the encoder 40 and the RF choke inductor L1. The voltage drives the encoder 40 to generate a coded square wave output, which is connected to the base of the BJT Q1 through resistor R2. When the coded square wave voltage is zero, the base of the BJT Q1 remains de-energized, and current does not flow through the inductor L1. When the coded square wave voltage is positive, the base of the BJT Q1 is energized through resistor R2. With the base of the BJT Q1 energized, current is allowed to flow across the base from the collector to the emitter and current is also allowed to flow across the inductor L1. When the square wave returns to a zero voltage, the base of the BJT Q1 is again de-energized.

When current flows across the choke inductor L1, the tank circuit capacitor C8 charges. Once the tank circuit capacitor C8 is charged, the tank circuit begins to resonate at the frequency determined by the circuit's LC constant. For example, a tank circuit having a 7 picofarad capacitor and an inductor L2 having a single rectangular loop measuring 0.7 inch by 0.3 inch, the resonant frequency of the tank circuit is 310 MHz. The choke inductor L1 prevents RF leakage into upstream components of the circuit (the PIC) because changing the magnetic field of the choke inductor L1 produces an electric field opposing upstream current flow from the tank circuit. To produce an RF signal, charges have to oscillate with frequencies in the RF range. Thus, the charges oscillating in the tank circuit inductor/tuned loop antenna L2 produce an RF signal of preferably 310 MHz. As the square wave output of the inverter turns the BJT Q1 on and off, the signal generated from the loop antenna 60 comprises a pulsed RF signal having a duration of 100-250 milliseconds and a pulse width determined by the encoder 40, (typically of the order of 0.1 to 5.0 milliseconds thus producing 20 to 2500 pulses at an RF frequency of approximately 310 MHz. The RF generator section 50 is tunable to multiple frequencies. Therefore, not only is the transmitter capable of a great number of unique codes, it is also capable of generating each of these codes at a different frequency, which greatly increases the number of possible combinations of unique frequency-code signals.

The RF generator 50 and antenna 60 work in conjunction with an RF receiver 270. More specifically, an RF receiver 270 in proximity to the RF transmitter 60 (within 300 feet) can receive the pulsed RF signal transmitted by the RF generator 50. The RF receiver 270 comprises a receiving antenna 270 for intercepting the pulsed RF signal (tone). The tone generates a pulsed electrical signal in the receiving antenna 270 that is input to a microprocessor chip that acts as a decoder 280. The decoder 280 filters out all signals except for the RF signal it is programmed to receive, e.g., the signal generated by the RF generator 50. An external power source is also connected to the microprocessor chip/decoder 280. In response to the intercepted tone from the RF generator 50, the decoder chip produces a pulsed electrical signal. The external power source connected to the decoder 280 augments the pulsed voltage output signal developed by the chip. This augmented (e.g., 120VAC) voltage pulse is then applied to a conventional relay 290 for changing the position of a switch within the relay. Changing the relay switch position is then used to turn an electrical device with a bipolar switch on or off, or toggle between the several positions of a multiple position switch. Zero voltage switching elements may be added to ensure the relay 290 activates only once for each depression and recovery cycle of the flextensional transducer element 12.

Switch Initiator System with Trainable Receiver

Several different RF transmitters may be used that generate different tones for controlling relays that are tuned to receive that tone. In another embodiment, digitized RF signals may be coded and programmable (as with a garage door opener) to only activate a relay that is coded with that digitized RF signal. In other words, the RF transmitter is capable of generating at least one tone, but is preferably capable of generating multiple tones. Most preferably, each transmitter is programmed with one or more unique coded signals. This is easily done, since programmable ICs for generating the tone can have over 230 possible unique signal codes which is the equivalent of over 1 billion codes. Most preferably the invention comprises a system of multiple transmitters and one or more receivers for actuating building lights, appliances, security systems and the like. In this system for remote control of these devices, an extremely large number of codes are available for the transmitters for operating the lights, appliances and/or systems and each transmitter has at least one unique, permanent and nonuser changeable code. The receiver and controller module at the lights, appliances and/or systems is capable of storing and remembering a number of different codes corresponding to different transmitters such that the controller can be programmed so as to actuated by more than one transmitted code, thus allowing two or more transmitters to actuate the same light, appliance and/or system.

The remote control system includes a receiver/controller for learning a unique code of a remote transmitter to cause the performance of a function associated with the system, light or appliance with which the receiver/controller module is associated. The remote control system is advantageously used, in one embodiment, for interior or exterior lighting, household appliances or security system. Preferably, a plurality of transmitters is provided wherein each transmitter has at least one unique and permanent non-user changeable code and wherein the receiver can be placed into a program mode wherein it will receive and store two or more codes corresponding to two or more different transmitters. The number of codes which can be stored in transmitters can be extremely high as, for example, greater than one billion codes. The receiver has a decoder module therein which is capable of learning many different transmitted codes, which eliminates code switches in the receiver and also provides for multiple transmitters for actuating the light or appliance. Thus, the invention makes it possible to eliminate the requirements for code selection switches in the transmitters and receivers.

Referring to FIGS. 30-35: The receiver module 101 includes a suitable antenna 270 for receiving radio frequency transmissions from one or more transmitters 126 and 128 and supplies an input to a decoder 280 which provides an output to a microprocessor unit 244. The microprocessor unit 244 is connected to a relay device 290 or controller which switches the light or appliance between one of two or more operation modes, i.e., on, off, dim, or some other mode of operation. One or more switch 222s are mounted on a switch unit 219 connected to the receiver and also to the microprocessor 244. The switch 222 is a two position switch that can be moved between the “operate” and “program” positions to establish operate and program modes. The switch 222 may comprise a two position slider switch, or it may also comprise a push button type switch. In one embodiment of the switch 222, the program is a “learn” mode, and activation of the learning function allows the receiver 101 to enter a code it has received into a memory 247. In another embodiment of the switch 222, the program is an “erase” mode, and activation of the erase function allows the receiver to remove a code it has received from the memory 247. The receiver preferably has two switches 222, corresponding to a “learn” pushbutton and an “erase” pushbutton.

In the invention, each transmitter, such as transmitters 126 and 128, has at least one unique code which is determined by the tone generator/encoder 40 contained in the transmitter. The receiver unit 101 is able to memorize and store a number of different transmitter codes which eliminates the need of coding switches in either the transmitter or receiver which are used in the prior art. This also eliminates the requirement that the user match the transmitter and receiver code switches. Preferably, the receiver 101 is capable of receiving many transmitted codes, up to the available amount of memory locations 247 in the microprocessor 244, for example one hundred or more codes.

When the controller 290 for the light or appliance is initially installed, the switch 222 is moved to the program mode and the first transmitter 126 is energized so that the unique code of the transmitter 126 is transmitted. This is received by the receiver module 101 having an antenna 270 and decoded by the decoder 280 and supplied to the microprocessor unit 244. The code of the transmitter 126 is then supplied to the memory address storage 247 and stored therein. Then if the switch 222 is moved to the operate mode and the transmitter 126 energized, the receiver 270, decoder 280 and the microprocessor 244 will compare the received code with the code of the transmitter 126 stored in the first memory location in the memory address storage 247 and since the stored memory address for the transmitter 126 coincides with the transmitted code of the transmitter 126 the microprocessor 244 will energize the controller mechanism 290 for the light or appliance to energize de-energize or otherwise operate the device.

In order to store the code of the second transmitter 128 the switch 222 is moved again to the program mode and the transmitter 128 is energized. This causes the receiver 270 and decoder 280 to decode the transmitted signal and supply it to the microprocessor 244 which then supplies the coded signal of the transmitter 128 to the memory address storage 247 where it is stored in a second address storage location. Then the switch 222 is moved to the operate position and when either of the transmitters 126 and 128 are energized, the receiver 270 decoder 280 and microprocessor 244 will energize the controller mechanism 290 for the light or appliance to energize de-energize or otherwise operate the device. Alternately, the signal from the first transmitter 126 and second transmitter 128 may cause separate and distinct actions to be performed by the controller mechanism 290.

Thus, the codes of the transmitters 126 and 128 are transmitted and stored in the memory address storage 247 during the program mode after which the system, light or appliance controller 290 will respond to either or both of the transmitters 126 and 128. Any desired number of transmitters can be programmed to operate the system, light or appliance up to the available memory locations in the memory address storage 247.

This invention eliminates the requirement that binary switches be set in the transmitter or receiver as is done in systems of the prior art. The invention also allows a controller to respond to a number of different transmitters because the specific codes of a number of the transmitters are stored and retained in the memory address storage 247 of the receiver module 101.

In yet another more specific embodiment of the invention, each transmitter 126 or 128 contains two or more unique codes for controlling a system, light or appliance. One code corresponds in the microprocessor to the “on” position and another code corresponds in the microprocessor 244 to the “off” position of the controller 290. Alternately, the codes may correspond to “more” or “less” respectively in order to raise or lower the volume of a sound device or to dim or undim lighting for example. Lastly, the unique codes in a transmitter 126 or 128 may comprise four codes which the microprocessor interprets as “on”, “off”, “more” and “less” positions of the controller 290, depending on the desired setup of the switches. Alternatively, a transmitter 126 or 128 may only have two codes, but the microprocessor 244 interprets repeated pushes of “on” or “off” signals respectively to be interpreted as dim up and dim down respectively.

In another embodiment of the invention, receiver modules 101 may be trained to accept the transmitter code(s) in one-step. Basically, the memory 247 in the microprocessor 244 of the receiver modules 101 will have “slots” where codes can be stored. For instance one slot may be for all of the codes that the memory 247 accepts to be turned on, another slot for all the off codes, another all the 30% dimmed codes, etc.

Each transmitter 126 has a certain set of codes. For example one transmitter may have just one code, a “toggle” code, wherein the receiver module 101 knows only to reverse its current state, if it's on, turn off, and if it's off, turn on. Alternatively, a transmitter 126 may have many codes for the complex control of appliances. Each of these codes is “unique”. The transmitter 126 sends out its code set in a way in which the receiver 101 knows in which slots to put each code. Also, with the increased and longer electrical signal that can be generated in the transmitter 126, a single transmission of a code set is achievable even with mechanically produced voltage. As a back-up, if this is not true, and if wireless transmission uses up more electricity than is available, some sort of temporary wired connection (upper not shown) between each transmitter and receiver target is possible. Although the disclosed embodiment shows manual or mechanical interaction with the transmitter and receiver to train the receiver, it is yet desirable to put the receiver in reprogram mode with a wireless transmission, for example a “training” code.

In yet another embodiment of the invention, the transmitter 126 may have multiple unique codes and the transmitter randomly selects one of the multitude of possible codes, all of which are programmed into the memory allocation spaces 247 of the microprocessor 244.

In yet another embodiment of the invention, the transmitter 126 signal need not be manually operated or triggered, but may as easily be operated by any manner of mechanical force, i.e., the movement of a window, door, safe, foot sensor, etc. and that a burglar alarm sensor might simultaneously send a signal to the security system and a light in the intruded upon room. Likewise, the transmitter 126 may be combined with other apparatus. For example, a transmitter 126 may be located within a garage door opener which can also turn on one or more lights in the house, when the garage door opens.

Furthermore, the transmitters 126, 128 can transmit signals to a central system or repeater which re-transmits the signals by wired or wireless means to lights and appliances. In this manner, one can have one transmitter/receiver set, or many transmitters interacting with many different receivers, some transmitters talking to one or more receivers and some receivers being controlled by one or more transmitters, thus providing a broad system of interacting systems and wireless transmitters. Also, the transmitters and receivers may have the capacity of interfacing with wired communications like SMARTHOME or BLUETOOTH, and ZIGBEE.

It is seen that the present invention allows a receiving system to respond to one of a plurality of transmitters which have different unique codes which can be stored in the receiver during a program mode. Each time the “program mode switch” 222 is moved to the program position, a different storage can be connected so that the new transmitter code would be stored in that address. After all of the address storage capacity has been used additional codes would erase all old codes in the memory address storage before storing a new one.

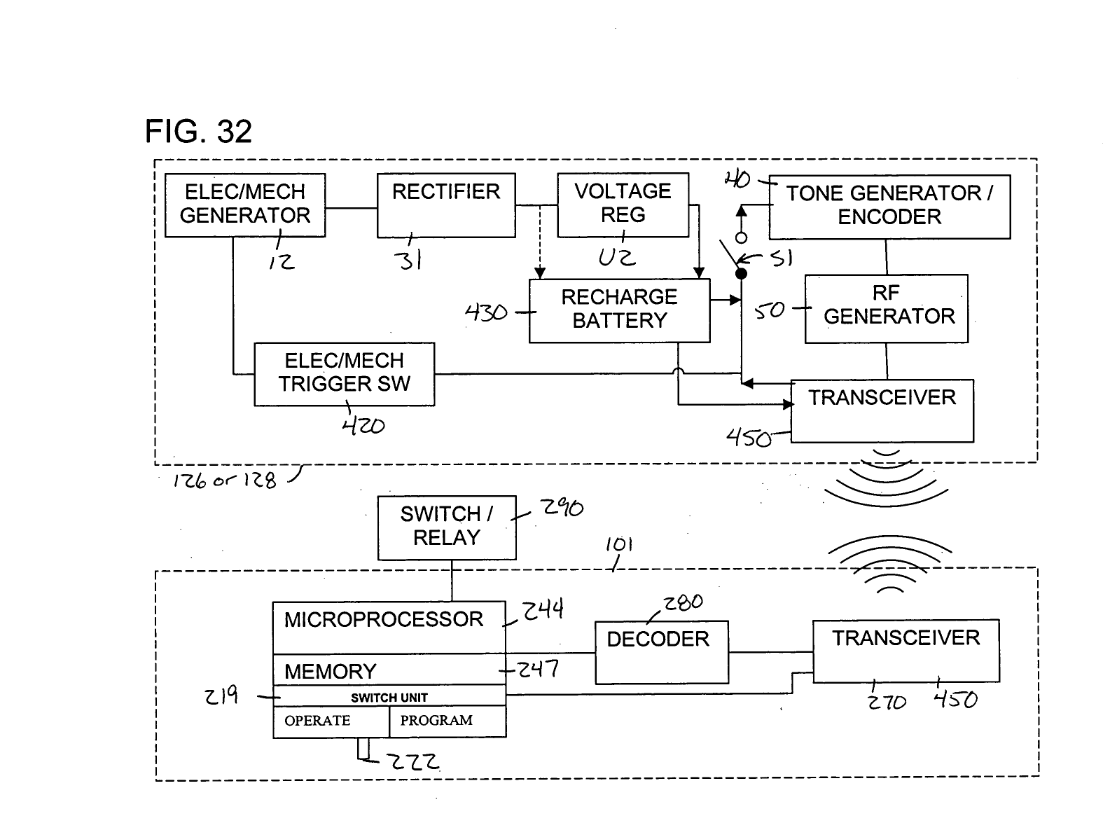

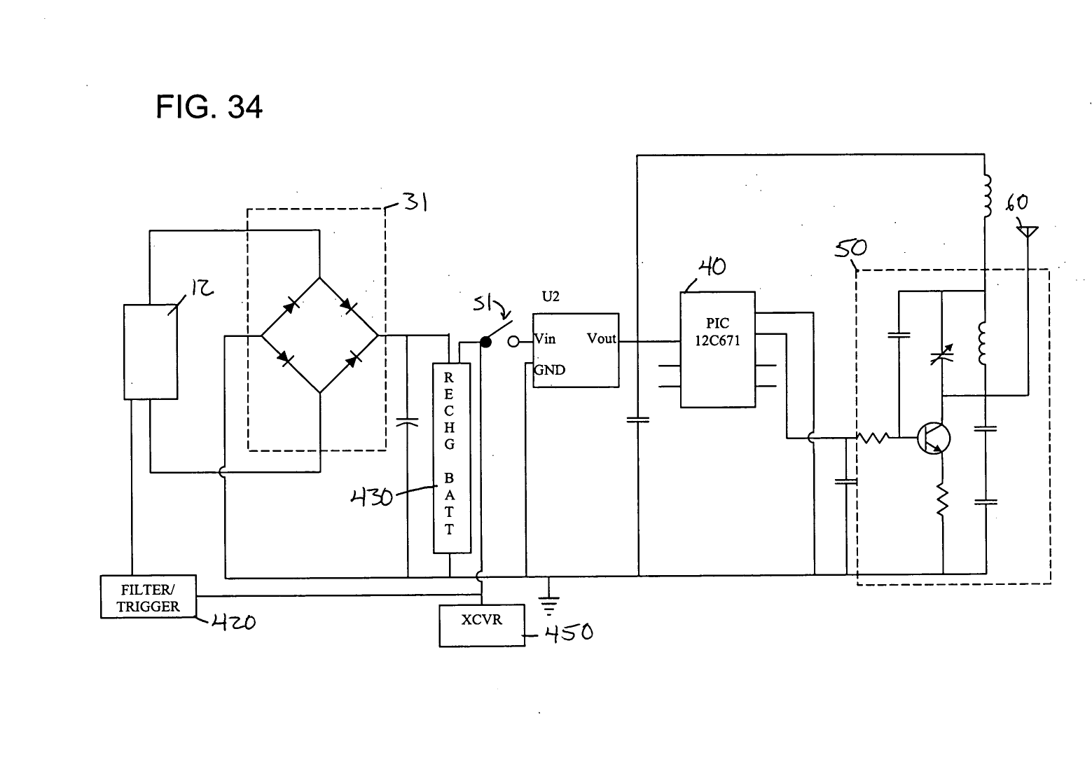

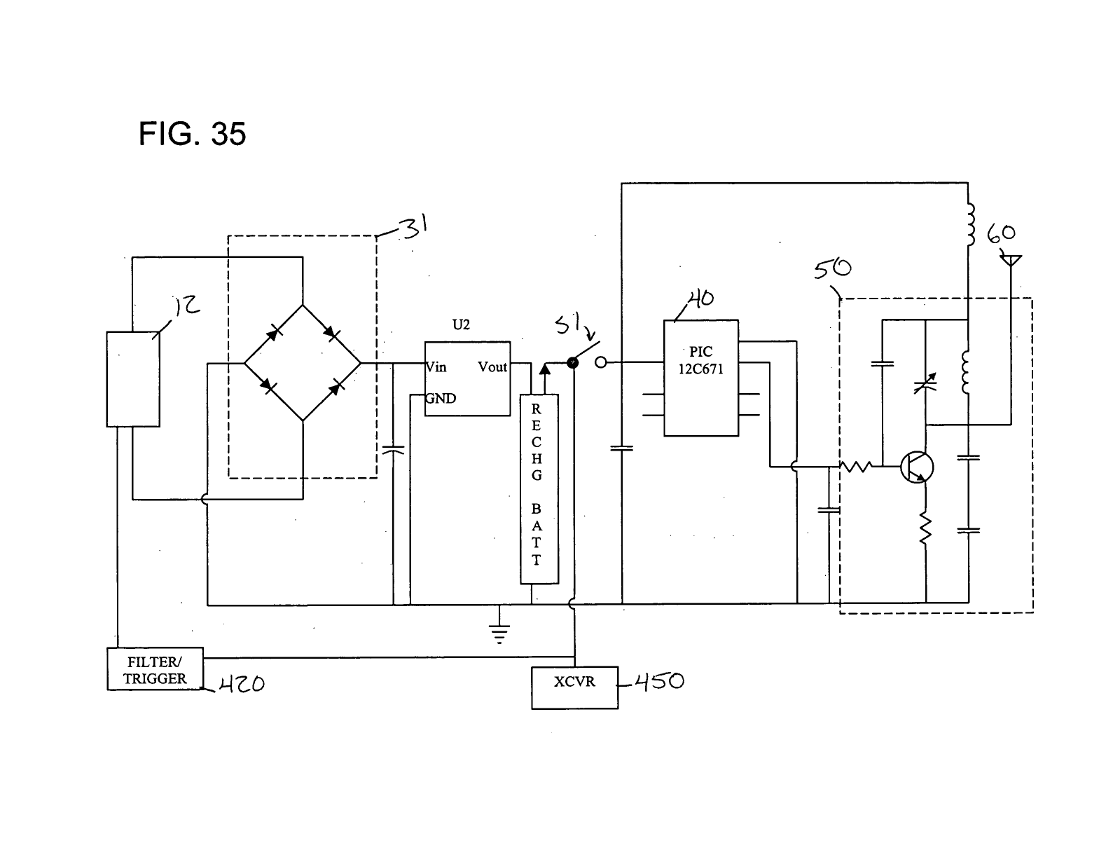

Referring now to FIGS. 32 and 34-35: While in the preferred embodiment of the invention, the actuation means has been described as from mechanical to electric, it is within the scope of the invention to include batteries in the transmitter to power or supplement the power of the transmitter. For example, long life rechargeable batteries 430 may be included in the transmitter circuitry and may be recharged through the electromechanical transducers 12. These rechargeable batteries 430 may thus provide backup power to the transmitter 50. The circuits illustrated in the figures are the same as those described herein above, with the exception of the addition of rechargeable batteries 430 in the circuit. In the circuit of FIGS. 32 and 34, the ground terminal of the battery is connected to ground and the positive terminal is connected to the output side of the rectifier before the voltage regulator. In the preferred circuit of FIGS. 32 and 35, the ground terminal of the battery is connected to ground and the positive terminal is connected to the output side of the voltage regulator U2 before the transmitter subcircuit 50.

Referring now to FIGS. 32 and 34-35: The circuit of FIG. 35 includes a rechargeable battery as in the circuit of FIG. 32. However, in this circuit, the output of the voltage regulator U2 is connected only to the positive/charging terminal of the rechargeable battery 430, i.e., the voltage regulator U2 output is not connected directly to the input side of the transmitter subcircuit 50. The output of the rechargeable battery 430 is connected to the input side of the transmitter subcircuit through a switch S1. The switch S1 may comprise a transistor. When the switch is closed/energized, electrical power is applied to the transmitter subcircuit. The switch may be energized when the deflection means activates the transducer 12. When the transducer 12 is deflected, an electrical output is produced, most of which is rectified and regulated, and then used of charge the battery 30. A small amount of the electrical power is tapped by a filter/trigger 420 from the transducer 12 (using for example a BJT connected between a grounded resistor and a second resistor between the BJT and the transducer 12), which electrical energy is applied to the switching device in order to electrically connected the battery to the transmitter subcircuit.

Referring again to FIGS. 32 and 34-35: In another embodiment of a self-powered transmitter circuit, the rechargeable battery 430 not only provides power for transmission of a coded signal, but also provides power to a low power consumption receiver 450. In the preferred embodiment, the receiver/transmitter comprises a single transceiver 450. The transceiver 450 is electrically connected to the battery as in FIGS. 32 and 34-35. However, in addition to transmitting in response to a trigger signal from the transducer 12 to energize the switch S1, the transceiver 450 will also transmit in response to the receiver portion of the transceiver's reception of an RF signal. In the preferred embodiment of the transceiver based circuit, when the transceiver 450 receives a coded signal corresponding one or more codes stored in the transmitter PIC (i.e., a polling code), then the transmitter portion of the transceiver 450 will transmit its coded RF signal. The transmitter RF code signal may correspond for example, to a transmission code of its current state for use as or to supplement an error detection code or a verification code. The battery supplemented transceivers 450 are preferably made compatible with present low-cost, very low power consumption, two-way, digital wireless communications standards such as ZIGBEE and BLUETOOTH.

Single and Multi-Function Switching

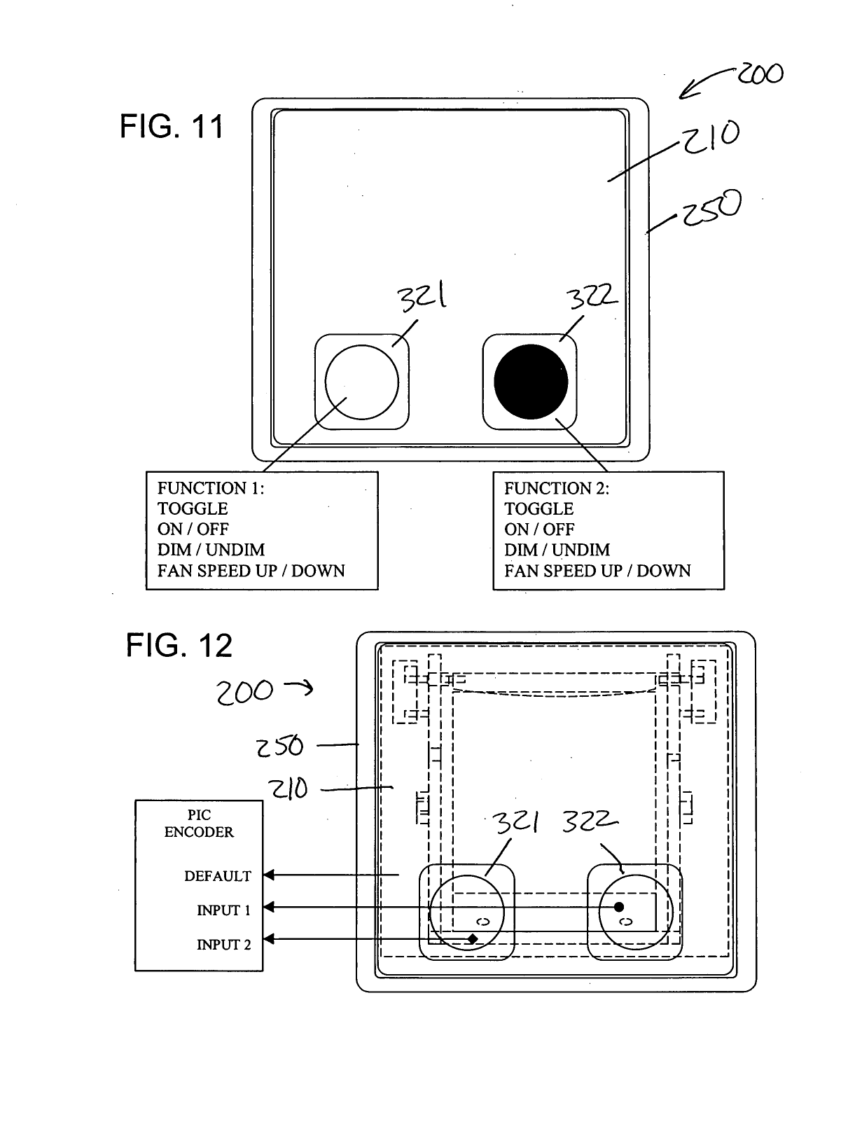

In the embodiments of the invention in FIGS. 11-12, and 31 pressure is applied directly to the actuator 12 by pushing on (mechanically activating) membrane switches or a keypad on a faceplate or button 210. The membrane switches comprise alphanumeric keys 321, 322 mounted on the top face 210a of the button. The membrane switches 321, 322 may also have function keys for commands such as “ENTER”, “LOCK”, “RESET”, “CANCEL”, “BACKSPACE”, “ARM”, “CANCEL” or the like. Additional commands available may include “ON”, OFF”, “DIM”, “UNDIM”, “ACTIVATE”, or a selection of toggles switches for selected devices including lights, electrical appliances, door locks, alarm systems, entry systems, fans, electronic devices and the like. These command functions are preferably represented by a symbol (such as a fan, a cycle symbol, or a dark or light dot) corresponding to a function rather than the actual word.

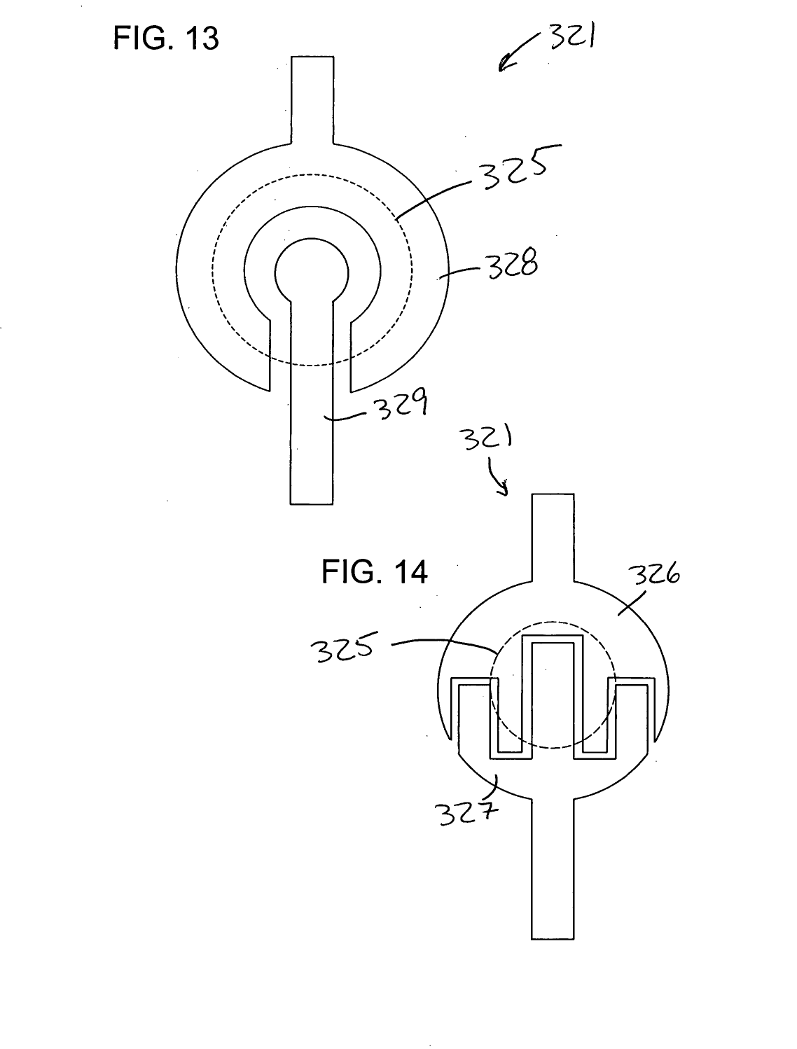

The individual buttons 321, 322 are easily depressible buttons that may take a variety of forms. As an example of types of keypad buttons that may be used are flat membrane switches 321, 322 and domed membrane switches 321, 322 and may further include LEDs or the like as indicators of the switch or button state. For example, flat membrane switches 321, 322 comprise a button overlay material 323 (on which is printed the alphanumeric or other command symbol) of polyester or polycarbonate with circuit connectors installed thereunder and are depressible with an applied force of 70-120 grams. Domed membrane switches 321, 322 have a better sense of touch and may be actuated with an operating force of 150-400 grams. The overlay 323 material comprises a flexible yet durable material such as plastic, polyester or polycarbonate with electrical connectors (such as in FIGS. 13-14) installed thereunder.

Basically, a membrane switch 321, 322 as its name implies an electrical switch created on a thin film or membrane. They are typically low power with maximum current ratings of around 1/10 of an amp. The circuitry for these devices is often somewhat elaborate since they frequently provide connections for a host of different input functions. The most common application for membrane switches 321, 322 is in a keyboard of some type. While not all keyboards are made of flexible materials, a great many are. The most common layouts are matrix type (i.e., rows and columns) and common line connections (i.e., a common trace plus some number of switches). Other structures are possible depending on the needs of the user including integration of electronic circuits, including passives devices, such as resistors, and land patterns for component mounting.

The conductor material used for membrane switches 321, 322 varies by application. Copper and polymer thick film (PTF) inks are the most common choices. Cost is normally a key factor when making the choice. Because of this, a substantial number of membrane switches have screen-printed PTF conductors consisting of metal-filled ink. Obviously, the normally much lower conductivity of printed inks limits the conductivity but they are not normally meant to carry current. Rather they are designed to send a simple signal pulse. Copper is employed when there is need to solder devices to the membrane or higher conductivity is needed, however, conductive adhesives have proven quite acceptable in most applications. The switch-life of a membrane contact can vary significantly from several thousand to many millions. The life-determining factors are many, and include such matters as materials of construction, contact design, switch travel, and operating conditions among many others.

One of the key elements of membrane switch design is involved in determining tactile feedback. This is that little snap or click that can be felt when a switch is pressed. Determining the right amount of force to be applied (the actuation pressure) is both an art and a science. There are basically two approaches to getting tactile feed back: metal dome contacts and polymer dome contacts. Metal dome tactile switches have spring metal dome over the contact area. When pressed, it snaps down to complete a circuit and snaps back when released. The shape and thickness of the metal (commonly spring stainless steel) will determine actuation force. They offer a long life but are not well suited to use with flex circuits. In contrast, polymer dome switches are embossed into the plastic film overlying the circuit. It is possible to get a good tactile feel from such contact, and though their life expectation is heavily influenced by their use environment, they can still endure millions of cycles. Furthermore, they have the advantage when it comes to cost since they reduce the number of parts, thus assembly time and complexity. Depending on the application, one can opt to not use tactile feedback. To this end, an auditory response method may be employed such as a small beep. Because of their extreme simplicity, these tend to be the lowest cost contacts of all.

Basic membrane switch contact designs are shown without an overlay in FIGS. 13 and 14. The contact area design is another important and interesting element of a membrane switch. Contact finish can vary. Gold, nickel, silver and even graphite may be used. The layout will vary with the type of contact used. For example, for a shorting contact, interdigitated fingers are often used. However, when a metal dome contact is employed, a central contact with a surrounding ring is frequently seen. The shorting contact 325 of FIG. 14 on the right is normally attached to a resilient material that holds it off the surface of the interdigitated fingers 326 and 327 when it is not pressed down. The shorting contact 325 of FIG. 13 is a metallic dome situated above concentric electrical traces 328 and 329, and when the dome 325 is pressed it contacts at least the outer circular trace 328, and when fully depressed contacts bother the inner 329 and outer 328 traces.

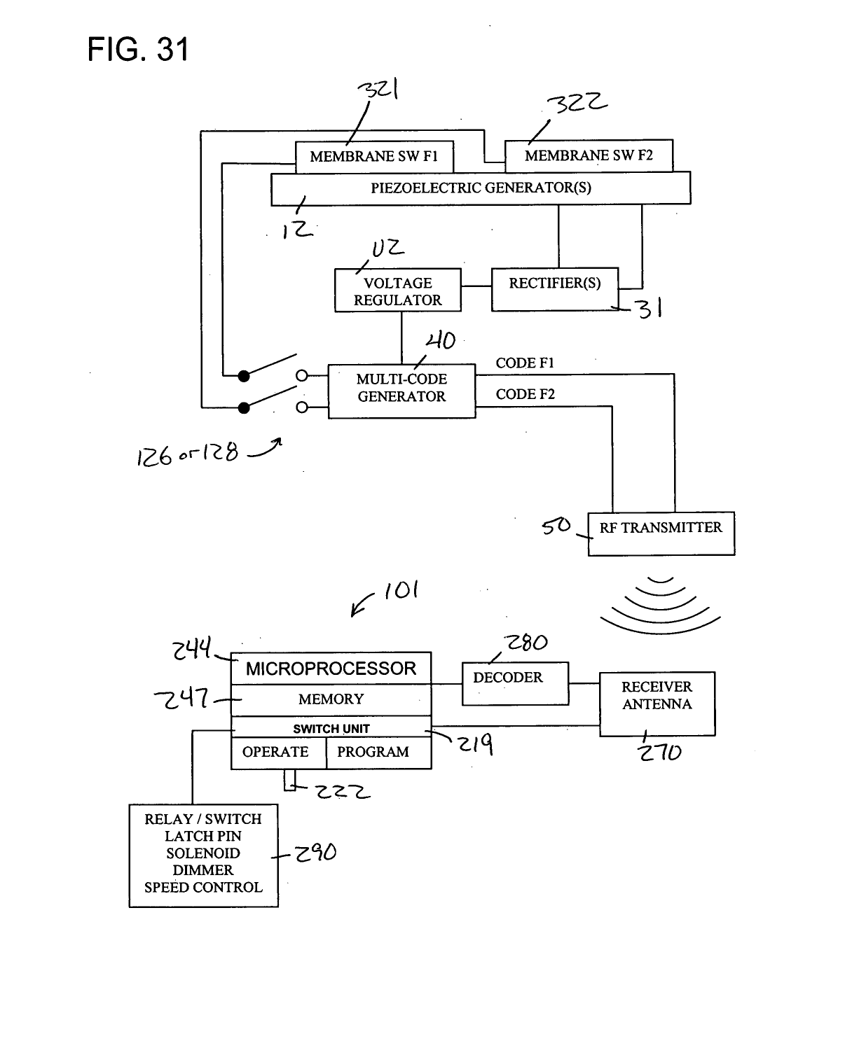

Referring now to FIGS. 12 and 31: The encoder 40 is programmable to generate a different code, dependent upon which of the multiple input connections is energized. The DC output of the voltage regulator U2 and the coded output of the encoder 40 are connected to an RF generator 50 via one or more membrane switches 321, 322 on the keypad 320 or faceplate/deflector 72. When a membrane switch 321, 322 is pressed, it creates electrical contact between the output of the voltage regulator U2 and one of the input pins to the PIC encoder 40. The encoder 40 output signal (code) is dependent upon which input pin has the voltage applied thereto. That is to say, the output signal or code is dependent upon and is different for each pin energized by the respective membrane switch that is pressed/closed. For example, when the mechanical deflector is pressed (but not a membrane switch 321 or 322), the encoder is energized and sends a default code to the RF transmitter. However, when a membrane switch 321 depressed, it creates electrical contact from the voltage regulator U2 to a different pin of the encoder 40, thus changing the output of the encoder to a different code from the default code. Likewise, when a different switch 322 depressed, it creates electrical contact from the voltage regulator U2 to a yet another pin of the encoder 40, thus changing the output of the encoder to a third code different from the default code and second code. These codes can correspond to a variety of functions for electrical appliances that receive the transmitted code such as a light switch, a dimmer, an electrical appliance power source, a security system, a motor controller, a solenoid, a piezoelectric transducer and a latching pin for a locking system. Exemplary functions that are associated with the membrane switches and concomitant coded outputs of the encoder 40 include “TOGGLE”, “ON”, “OFF”, “DIM”, “UNDIM/BRIGHTEN”, “LOCK”, “UNLOCK”, “SPEED UP”, “SLOW DOWN”, “ACTIVATE”, “RESET” or the like command functions for electrical appliances connected to the receiver.

In operation: The positive voltage output from the voltage regulator U2 is connected the encoder 40 via a default pin and to one or more different pins through one or more respective membrane switches 321, 322. The positive voltage output from the voltage regulator U2 is also connected the RF choke inductor L1. The voltage drives the encoder 40 to generate a coded square wave output (which code depends on the pin energized), which is connected to the base of the BJT Q1 through resistor R2. When the coded square wave voltage is zero, the base of the BJT Q1 remains de-energized, and current does not flow through the inductor L1. When the coded square wave voltage is positive, the base of the BJT Q1 is energized through resistor R2. With the base of the BJT Q1 energized, current is allowed to flow across the base from the collector to the emitter and current is also allowed to flow across the inductor L1. When the square wave returns to a zero voltage, the base of the BJT Q1 is again de-energized.

Several different RF transmitters 126, 128 may be used that generate different codes for controlling relays that are trained to receive that code. In another embodiment, digitized RF signals may be coded and programmable (as with a garage door opener) to only activate a relay that is coded with that digitized RF signal. In other words, the RF transmitter is capable of generating at least one code, but is preferably capable of generating multiple codes. Most preferably, each transmitter is programmed with one or more unique coded signals. This is easily done, since programmable ICs for generating the code can have over 230 possible unique signal codes which is the equivalent of over 1 billion codes. Most preferably the invention comprises a system of multiple transmitters and one or more receivers for actuating building lights, appliances, security systems and the like. In this system for remote control of these devices, an extremely large number of codes are available for the transmitters for operating the lights, appliances and/or systems and each transmitter has at least one unique, permanent and non-user changeable code. The receiver and controller module at the lights, appliances and/or systems is capable of storing and remembering a number of different codes corresponding to different transmitters (or different function buttons/membrane switches on a single transmitter) such that the controller can be programmed so as to be actuated by more than one transmitted code, thus allowing two or more transmitters to actuate the same light, appliance and/or system.

The remote control system includes a receiver/controller for learning one or more unique codes of a remote transmitter to cause the performance of a function associated with the system, light or appliance with which the receiver/controller module is associated. The remote control system is advantageously used, in one embodiment, for interior or exterior lighting, household appliances or security system. Preferably, a plurality of transmitters is provided wherein each transmitter has at least one unique and permanent non-user changeable code and wherein the receiver can be placed into a program mode wherein it will receive and store two or more codes corresponding to two or more different transmitters. The number of codes which can be programmed into transmitters can be extremely high as, for example, greater than one billion codes. The receiver has a decoder module therein which is capable of learning many different transmitted codes, which eliminates code switches (dipswitches) in the receiver and also provides for multiple transmitters for actuating the light or appliance. Thus, the invention makes it possible to eliminate the requirements for code selection switches in the transmitters and receivers.

Referring to FIGS. 30-31: The receiver module includes an antenna 270 for receiving radio frequency transmissions from one or more transmitters 126 and 128 and supplies a received RF signal as an input to a decoder 280 which provides an output to a microprocessor unit 244. The microprocessor unit 244 is connected to a relay device 290 or controller which switches the light or appliance between one of two or more operation modes, i.e., on, off, dim, or some other mode of operation. A switch 222 is mounted on a switch unit 219 connected to the receiver and also to the microprocessor 244. The switch 222 is a two position switch that can be moved between the “operate” and “program” positions to establish operate and program modes.

In the invention, each transmitter, such as transmitters 126 and 128, has at least one unique code which is determined by the tone generator/encoder 40 contained in the transmitter. The receiver unit 101 is able to memorize and store a number of different transmitter codes which eliminates the need of coding switches in either the transmitter or receiver which are used in the prior art. This also eliminates the requirement that the user match the transmitter and receiver code switches. Preferably, the receiver 101 is capable of receiving many transmitted codes, up to the available amount of memory locations 247 in the microprocessor 244, for example one hundred or more codes.

When the controller 290 for the light or appliance is initially installed, the switch 222 is moved to the program mode and the first transmitter 126 is energized so that the unique code of the transmitter 126 is transmitted. This is received by the receiver module 101 having an antenna 270 and decoded by the decoder 280 and supplied to the microprocessor unit 244. The code of the transmitter 126 is then supplied to the memory address storage 247 and stored therein. Then if the switch 222 is moved to the operate mode and the transmitter 126 energized, the receiver 270, decoder 280 and the microprocessor 244 will compare the received code with the code of the transmitter 126 stored in the first memory location in the memory address storage 247 and since the stored memory address for the transmitter 126 coincides with the transmitted code of the transmitter 126 the microprocessor 244 will energize the controller mechanism 290 for the light or appliance to energize de-energize or otherwise operate the device.

In order to store the code of the second transmitter 128 the switch 222 is moved again to the program mode and the transmitter 128 is energized. This causes the receiver antenna 270 and decoder 280 to decode the transmitted signal and supply it to the microprocessor 244 which then supplies the coded signal of the transmitter 128 to the memory address storage 247 where it is stored in a second address storage location. Then the switch 222 is moved to the operate position and when either of the transmitters 126 and 128 are energized, the receiver antenna 270, decoder 280 and microprocessor 244 will energize the controller mechanism 290 for the light or appliance to energize de-energize or otherwise operate the device. Alternately, the signal from the first transmitter 126 and second transmitter 128 may cause separate and distinct actions to be performed by the controller mechanism 290.

Thus, the codes of the transmitters 126 and 128 are transmitted and stored in the memory address storage 247 during the program mode after which the system, light or appliance controller 290 will respond to either or both of the transmitters 126 and 128. Any desired number of transmitters can be programmed to operate the system, light or appliance up to the available memory locations in the memory address storage 247.

Multi-Gang Powered and Self-Powered Switches

An improvement to the present invention relates generally to a multi-gang wall switch for wired and self-powered wireless control of electrical appliances. More particularly, the present invention relates to a multi-gang wall switch incorporating both a conventional wired switch and at least one self-powered switch initiator device to generate an activation signal for a latching relay for energizing lights, appliances and the like.

This invention is safe because it eliminates the need for 120 VAC (220 VAC in Europe) lines to be run to each switch in the house. Instead the higher voltage overhead AC lines are only run to the appliances or lights, and they are actuated through the self-powered switching device and relay switch. The invention also saves on initial and renovation construction costs associated with cutting holes and running the electrical lines to/through each switch and within the walls. The invention is particularly useful in historic structures undergoing preservation, as the walls of the structure need not be destroyed and then rebuilt. The invention is also useful in concrete construction, such as structures using concrete slab and/or stucco construction by eliminating the need to have wiring on the surface of the walls and floors of these structures. Furthermore, remote transmitters may be fitted with holes and screws to mount over existing switch boxes in walls. Also, a transmitter may be mounted over the existing switch boxes using adhesives, magnetic mounting, screws, bolts, hook and loop fasteners, snaps, hooks, or other fasteners.

The present system allows a user to install an additional switch adjacent existing switches without the necessity of installing new wiring, and without the necessity of replacing the existing switch with another system. By including a wireless switch in a wall mounting plate with an adjacent wall switch for connection to 110V house electricity, conventional single- and multiple-gang powered wall switches may be reconfigured as multiple gang switches having a greater number of functions, without having to rewire or replace the existing switch.

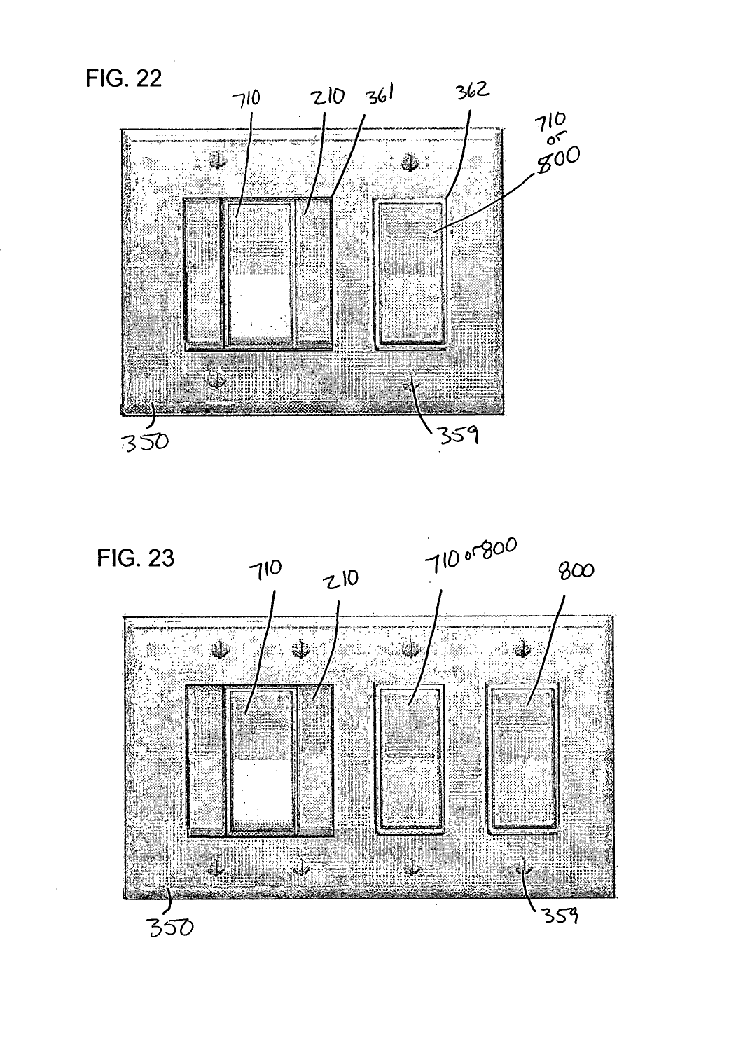

FIG. 11 is a plan view of a faceplate 250 and button 210 forming the switch housing 200, with the button 210 having two membrane switches 321, 322 thereon for direct connection to a transmitter circuit to provide separate functions. FIG. 12 is a plan view of the faceplate 250 and switch housing 200 of FIG. 11 showing a deflection assembly and piezoelectric generator in ghost therein. Exemplary types of membrane switch contacts 321, 322 used for a round membrane switch are shown in FIG. 13 which is a plan view of a domed contact switch 321 showing disconnected concentric circuit traces 328 and 329, with the domed shorting contact 325 in ghost thereabove. FIG. 14 which is a plan view of a membrane switch 321 showing disconnected interdigitated circuit traces 326 and 327, with the shorting contact 325 in ghost thereabove. Square membrane switches with similar interdigitation and shorting contacts may also be used and are preferred in the multifunction switches of FIGS. 22-26.

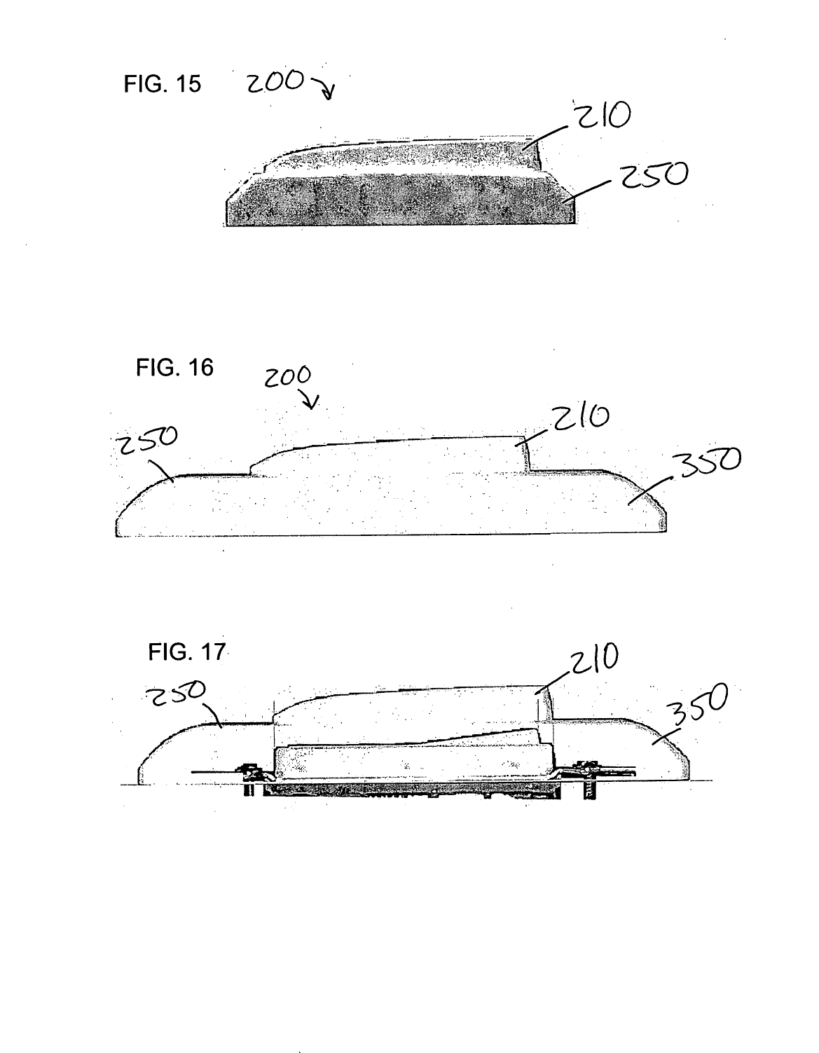

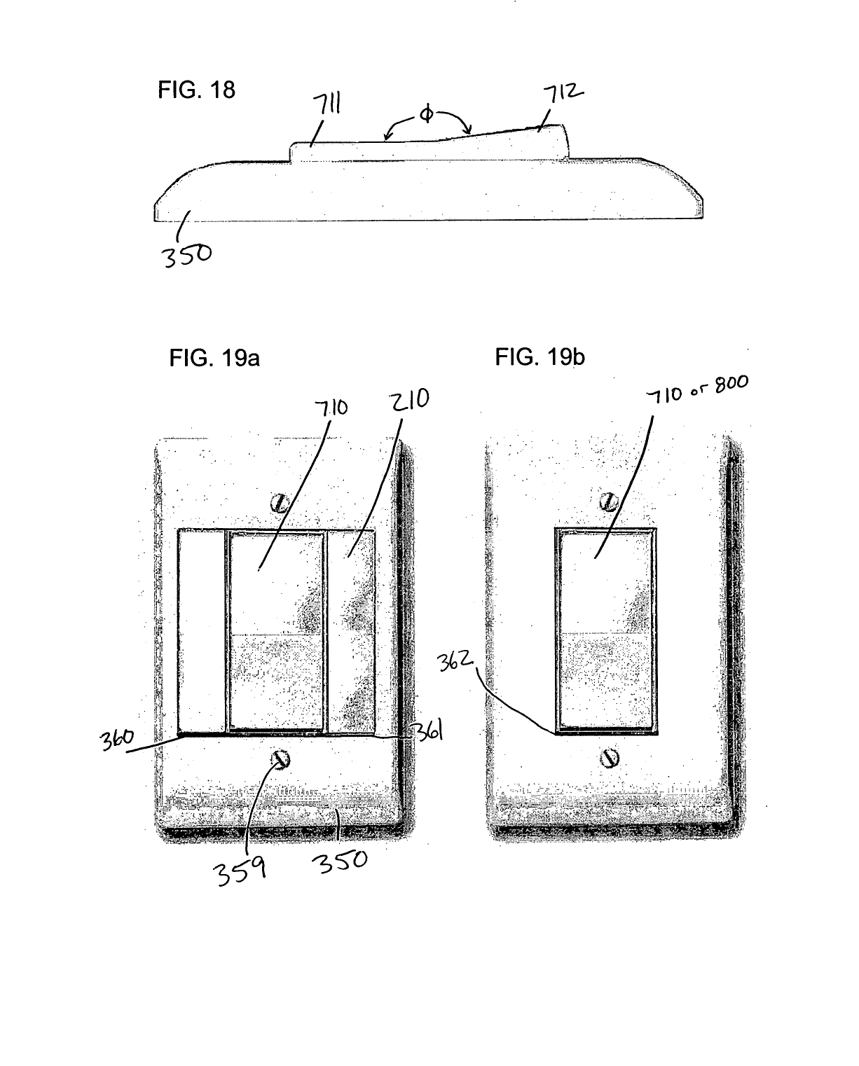

FIG. 15 is a side elevation view of the faceplate (frame) 250 and button 210 forming the switch casing 200 of FIGS. 11-12. FIG. 16 is a side elevation view of the faceplate 250 and switch casing of FIG. 15 having a larger wall mount 350 surrounding the central switch button 210. FIG. 17 is a side elevation view of a conventional wired wall switch superimposed over the side elevation view of FIG. 16. FIG. 18 is a side elevation view of a modified embodiment of the switch in FIG. 16 having a faceplate that conforms to the elevation of the conventional wired switch of FIG. 17 and mountable adjacently or within the same wall mounting frame as the conventional wired switch of FIG. 17. FIGS. 19a and 19b are plan views of a single function toggle wireless switch as in FIG. 18 having a faceplate that conforms to the elevation of the conventional wired switch of FIG. 17.

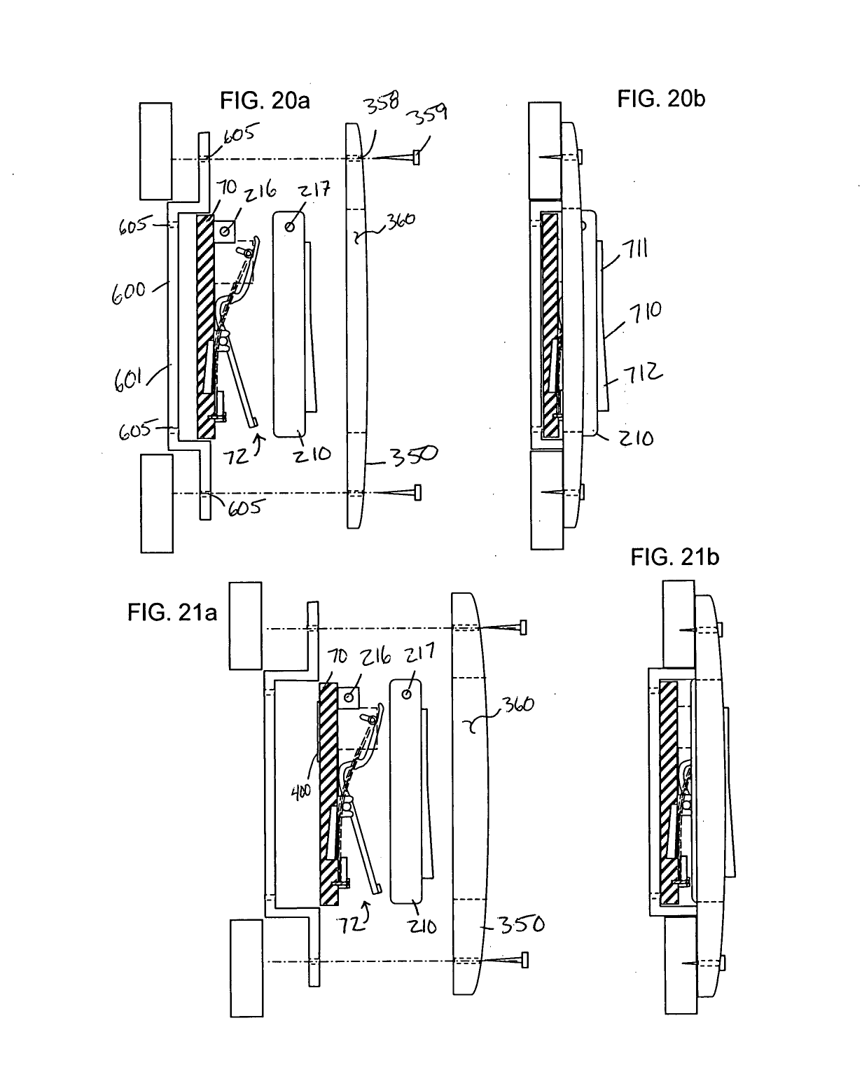

Referring now to FIGS. 20a-b and 21a-b: FIGS. 20a and 21a show expanded views of a wireless switch and its casing 200 components and wall mounting hardware. Each switch comprises an actuation mechanism 72 for the electromechanical generator and circuit components which are mounted on a base 70. The base 70 is received within a mounting bracket 600 which fits with a hole in the wall or mounting surface to provide a recessed mount. The bracket 600 comprises a preferably metallic plate having a recessed portion 601 which fits within the hole in the wall and two flanged portions 602 and 603 which abut the surface of the wall when the recessed portion 601 is in the hole, The recessed portion 601 preferably has the same dimensions in depth, length and width as the base 70 in order to receive the base 70 therein. The recessed portion 601 may have one or more screw holes 605 therethrough to allow mounting of the base plate 70 thereto. The flanged portions 602, 603 preferably also have screw holes 605 therethrough to allow attachment of the flanged portion 602, 603 to the wall, and/or to allow mounting of the faceplate 250 or 350 to the flange 600 and/or wall.

The base plate 70 has a pair of hinge pins 216 mounted thereon, opposite the side having the crossbar mechanism. The hinge pins 216 fit within hinge holes 217 in the button 210 to allow the button to be pivotably mounted to the base 70, whereby the button 210 may pivot about the hinge pins 216 and contact the crossbar to actuate the deflection mechanism 72 when the button 210 is pressed. The frame 250 or faceplate 350 has a button aperture 360 therethrough having the same dimensions as the button 210, in order that the faceplate 250, 350 may be mounted over the button 210, yet allow the button 210 to pivot about the hinge pins 216 when pressed without interfering with the movement of the button 210. The frame mounts over the button 210 and to the wall via screw holes 358 in the frame 350, which screws 359 can mount the frame 350 directly to the wall, or may be mounted through the screw holes 605 in the flange 600. Since the bracket 600 is metallic, it is also desirable that the antenna 60 on the base 70 may be electrically connected to the bracket 600 via a screw or wire so that the bracket 600 may increase the reception capability of the antenna 60. FIGS. 20b and 21b show the assembled switches and mounting plates with the recessed bracket 600. The bracket 600 of FIGS. 21a and 21b is recessed more deeply into the wall or mounting surface in order that the button 210 extend a shorter distance above the wall than does the button 210 of FIG. 20b, thereby allowing a narrower profile switch in relation to the frame 350 and the wall.

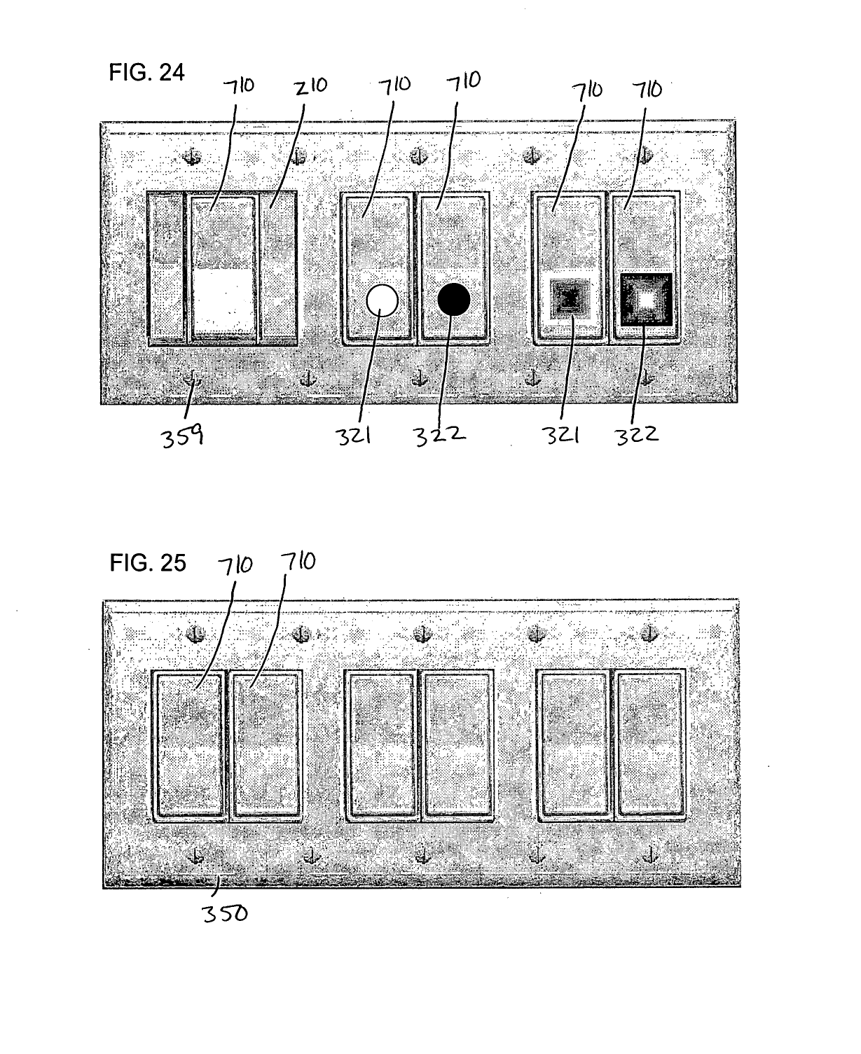

It is preferably in some installation that the button have a raised portion that looks similar to a “DECORA”™ style switch as manufactured by Leviton, especially in instances when the wireless switch is to be mounted adjacent hard-wired DECORA style switches 800. The button 210 of the wireless switch has a rectangular profile measuring approximately 3 inches by 3 inches. In the single toggle wireless switch, the button 210 face 210a has an essentially square, flat profile on the plan view of an approximately 3 inch square as shown in FIG. 11. In the DECORA style button 210 of FIGS. 18, 19a-b, 20a-b and 210a-b, centered between the left and right edges of the button 210 is a raised portion 710 measuring approximately 1.5 inch by 3 inches, having a top half 711 and bottom half 712. The top half 711 of the raised portion 710 is essentially parallel to the underlying button 210. As shown in FIG. 18 the bottom half 712 tends upwardly from the button 210, the upper half 711 and lower half 712 of the raised portion 710 forming an obtuse angle φ, of approximately 160-178 degrees with relation to each other. While it has been described that a single raised portion 710 may be placed on a single rectangular button 210, it is also contemplated to have two raised portions 710 directly adjacent each other on the button 210 as shown in FIGS. 24-29. These adjacent raised portions 710 may have membrane switches 321 and 322 attached thereto to provide multiple switching commands from one transmitter 126 or 128 thereunder. In FIG. 29, it is also shown that it is desirable to have the wireless switch installed in a mounting plate 350 adjacent to other types of hard wired switches not limited to the DECORA style switch 800, but also conventional flip lever type switches 801 or rotary switches 802 such as those used for dimmer or fan speed controls.

Referring to FIGS. 22-29: The invention incorporates a variety of wall mounting plates 350 that allow for installation of at least one wireless switch (including a single toggle switch or a multifunction switch, and further including a self-powered switch and/or a battery powered/supplemented switch) adjacent one or more conventional powered hard-wired wall switches 800, 801, 802. The wireless switch has a pivoting button 210 that has a plan view as in FIG. 11, 19, 22 or 23 which fits within a substantially square aperture 360 through the wall mounting plate 350. The button 210 of the wireless switch is designed to appear similar to the “DECORA”™ style switch as manufactured by Leviton, which has a rectangular profile measuring approximately 1.5 inches by 3 inches. In the single toggle wireless switch, the button 210 has essentially square, flat profile on the plan view of an approximately 3 inch square. Centered between the left and right edges of the button 210 is a raised portion 710 measuring approximately 1.5 inch by 3 inches, having a top and bottom half 711, 712. The top half 711 of the raised portion 710 is essentially parallel to the underlying button 210 surface. As shown in FIG. 18 the bottom half tends upwardly from the button 210 and upper half of the raised portion 710 forming an obtuse angle φ, of approximately 160-178 degrees.

Referring again to FIGS. 19a and 19b: An aperture is provided in the mounting frame 350 through which the button 210 extends. In FIG. 19a, the aperture 360 may comprise an essentially square aperture 361 through which the whole button 210 extends. In FIG. 19, the aperture may be configured as a rectangular aperture 362, through which only the raised portion 710 of the button 210 extends. The remainder of the button 210 is enclosed behind the mounting plate 350.

FIG. 22 is a plan view of a single function toggle switch as in FIG. 19 in a wall mounting plate adjacent either a hard wired switch 800 or a wireless switch as in FIG. 19b. For a multifunction wireless switch as in FIGS. 24-29, the button 210 features two raised portions 710 (having the same dimensions as the single raised portion above) which fit exactly on the dimensions of the approximately 3 by 3 inch square faceplate. The lower half of the raised portions 710 as in FIG. 24 may each have one or more membrane switches 321, 322 thereon for sending different function commands dependant on which membrane switch is pressed. FIG. 24 shows multifunction switches that have colored circular membrane switches as in FIG. 11. However, it is preferred that the membrane switches be square (as in the right most switches in FIG. 24) in order to maximize the contact area for activation of the membrane switch. Furthermore, the membrane switches need not be colored as in FIG. 24, but may be essentially translucent or colored substantially identical to the color of the button 210 and wall mounting plate 350 as in FIG. 25.

Each of the wall mounting plates 350 is provided with screw holes 358 for mounting of the mounting plate 350 and switches therein to a wall or other mounting surface. The holes adjacent the conventional wired switches are designed to align with the mounting holes of the electrical junction box where one or more existing wired switches are located. The screw holes 358 adjacent the wireless switch(es) are also designed to align with the mounting holes of multi-gang electrical junction box where one or more existing wired switches are or were located.

The wall mounting plate 350 may extend past the underlying electrical junction box (and over the underlying wall) in the case where a single gang switch is being changed to a multi-gang switch. Likewise, a double or triple multi-gang switch plate may be changed to a triple or quadruple-gang plate. In this case, the screw holes 358 adjacent the wireless switch(es) may either align with receiving screw holes in the electrical junction box, or the screws may attach directly to the underlying wall or other mounting surface.

The self powered switch may be adjacent at least one aperture 360 in the wall mounting plate 350 that conforms to conventional wired switches. The apertures 362 in the wall mounting plate for the conventional wired switches include an aperture for the “DECORA”™ style switch as manufactured by Leviton, which has a rectangular profile measuring approximately 1.5 inches by 3 inches and which may also conform to the a single raised portion 710 of a wireless switch. Also included are apertures 360 for conventional wired wall toggle switches such as are most commonly available measuring approximately 7/16 inch by 15/16 inch and generally in the range of 5/16-½ inch by ¾ to 1+¼ inch. The aperture 360 may also include a circular aperture accommodating conventional wired rotary, rheostat, push button and dimmer switches.

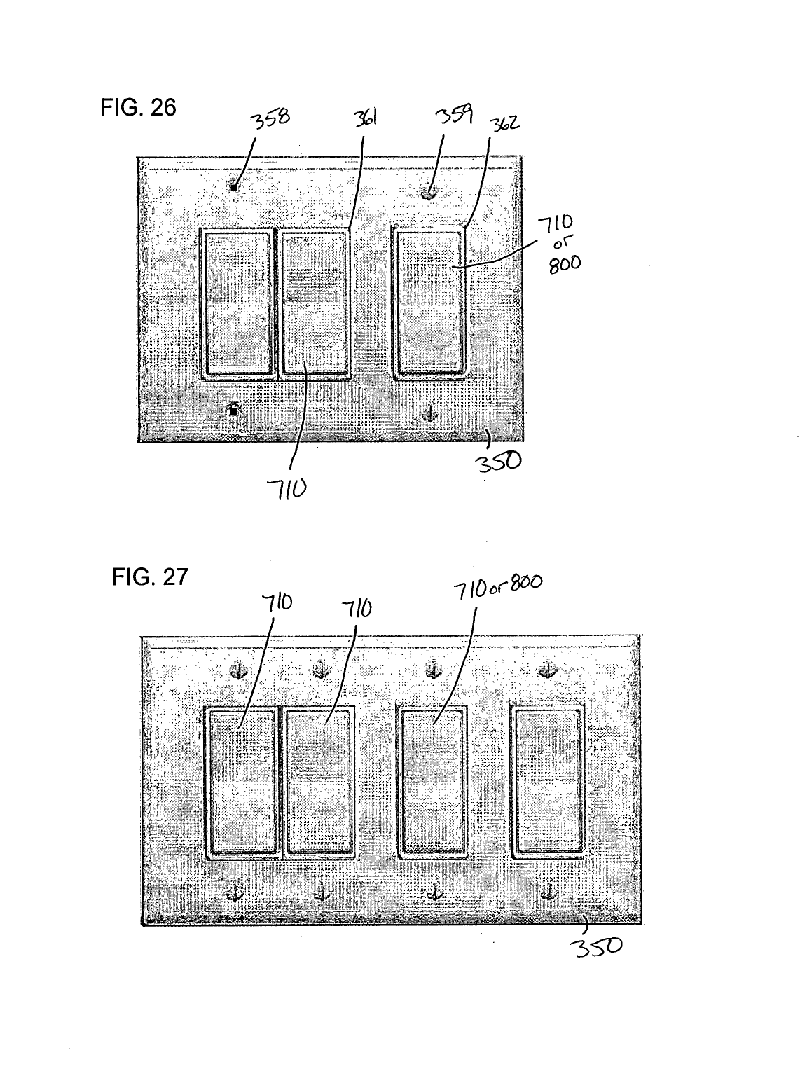

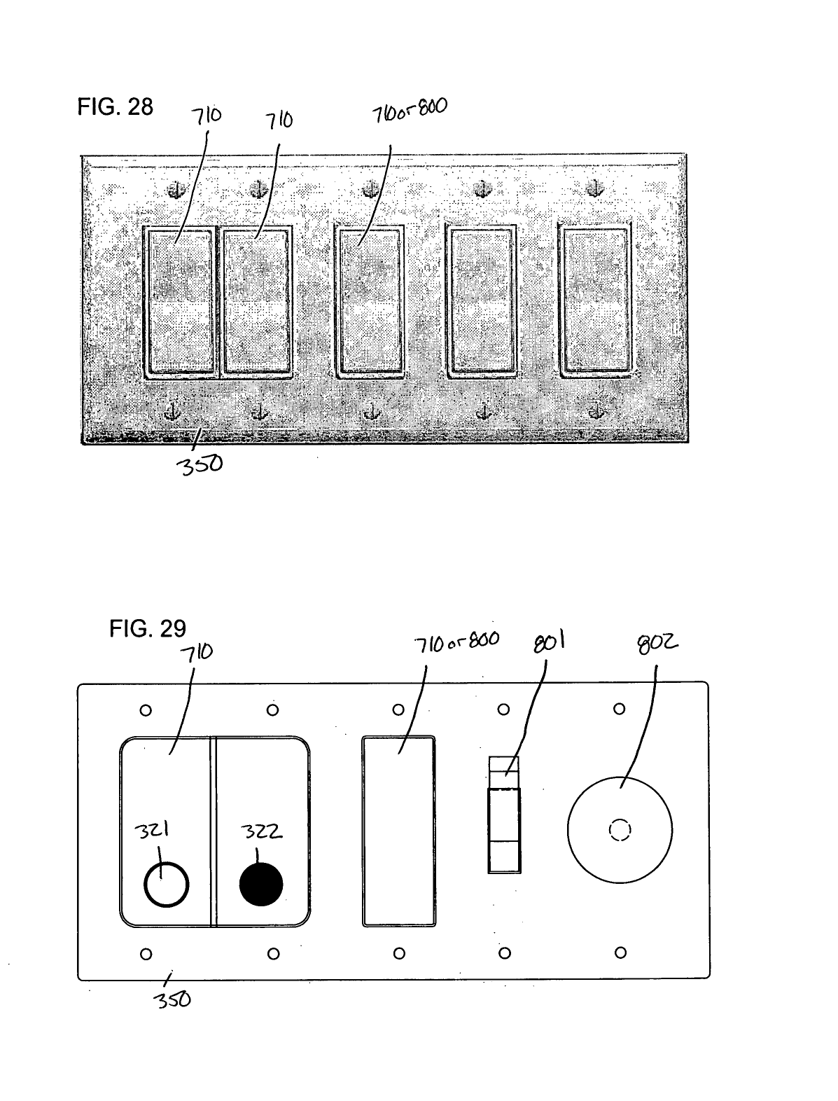

FIGS. 19-29 are examples of common wireless and wired switch combinations with a single or multi-gang mounting plate. FIG. 22 is a plan view of a single function toggle switch as in FIG. 19a in a wall mounting plate adjacent one conventional wired switch 800 or wireless raised portion 710 as in FIG. 19b. The switch on the right is the standard “Decora” hard-wired switch 800, or the DECORA style raised portion 710 or a wireless switch. (For future reference, stating a switch is conventional wired or DECORA style switch implies that the aperture therefor will also accommodate the raised portion 710 of a wireless switch) It is mounted in a single-gang or double-gang junction box. FIG. 23 is a plan view of a single function toggle switch as in FIG. 19a in a wall mounting plate adjacent two conventional wired switches as in FIG. 19b. FIG. 24 is a plan view of a single function toggle switch as in FIG. 19a in a wall mounting plate 350 adjacent two multifunction wall switches as in FIGS. 18 and 11. FIG. 25 is a plan view of three multifunction wall switches as in FIGS. 18 and 11 mounted adjacently in a wall mounting plate. The two switches together on the left are a single “Double-Toggle” or other multifunction Lightning Transmitter as in FIG. 11. The two left frame screws 358 mount directly into the wall. FIG. 26 is a plan view of a multifunction wall switch as in FIGS. 18 and 11 in a wall mounting plate 350 adjacent one conventional wired switch as in FIG. 19b. FIG. 27 is a plan view of a multifunction wall switch as in FIGS. 18 and 11 in a wall mounting plate adjacent two conventional wired switches as in FIG. 19b. FIG. 28 is a plan view of a multifunction wall switch as in FIGS. 18 and 11 in a wall mounting plate adjacent three conventional wired switches as in FIG. 19b. FIG. 29 is a plan view of a multifunction wall switch as in FIGS. 18 and 11 in a wall mounting plate 350 adjacent a conventional wired switch as in FIG. 19b, and a conventional small toggle wall switch 801 and a conventional push-button rotary wall dimmer switch 802.

While the above description contains many specificities, these should not be construed as limitations on the scope of the invention, but rather as an exemplification of one preferred embodiment thereof. Many other variations are possible, for example:

In addition to piezoelectric devices, the electroactive elements may comprise magnetostrictive or ferroelectric devices;

Rather than being arcuate in shape, the transducer 12 may normally be flat and still be deformable;

Multiple high deformation piezoelectric transducers may be placed, stacked and/or bonded on top of each other, as well as transducers having multiple layers on a single substrate;

Multiple piezoelectric transducers may be placed adjacent each other to form an array;

Larger, multilayer and different shapes of THUNDER elements may also be used to generate higher impulses;

The piezoelectric elements may be flextensional transducers; direct mode piezoelectric transducers, and indirect mode piezoelectric transducers;

A bearing material may be disposed between the transducers and the recesses or switch plate in order to reduce friction and wearing of one element against the next or against the frame member of the switch plate;

Other means for applying pressure to the transducer may be used including simple application of manual pressure, rollers, pressure plates, toggles, hinges, knobs, sliders, twisting mechanisms, release latches, spring loaded devices, foot pedals, game consoles, traffic activation and seat activated devices.

We claim:

1. A self powered switch initiation system comprising:
A first electromechanical generator having first and second ends;
said first electromechanical generator being adapted to produce an output voltage upon deformation of said electromechanical generator;
a base for retaining at least one end of said electromechanical generator;
said base further comprising retention means for retaining said first end, said second end or said first and second ends of said electromechanical generator;
a deflector for deforming said electromechanical generator; said deflector being adapted to apply a mechanical force to said electromechanical generator;
a first radio-frequency (RF) transmitter electrically connected to said electromechanical generator, said radio-frequency generator comprising;
a rectifier having an input side and an output side, said input side of said rectifier being electrically connected to said electromechanical generator;
a voltage regulator having an input side and an output side, said input side of said voltage regulator being electrically connected to said out0put of said rectifier;
an encoder having a first input and an output side, said first input being electrically connected to said output side of said voltage regulator;
an output signal at said output side of said encoder being a binary coded voltage signal;
an RF generator having and input side and an output side, said input side of said RF generator being electrically connected to said output side of said encoder;
an antenna having an input side connected to said output side of said RF generator;
an output signal of said radio-frequency generator being a RF signal modulated by said binary coded voltage signal of said encoder;
said RF signal being transmitted by said antenna;
a pair of hinge pins mounted on said base;
a button for activating said deflector, said button comprising;
a button face, and four button walls extending perpendicularly from said button face;
a pair of button hinge holes in two opposing walls of said button, said button holes being pivotably attached to said button hinge pins;
whereby upon application of a force to said button face, said button pivots on said hinge pins and applies a force to said deflector;
a mounting plate for mounting said base to a mounting surface;
said mounting plate having a mounting plate face and four mounting plate walls extending perpendicularly from said mounting plate face;
said mounting plate face having an aperture therethrough, said aperture being of substantially the same dimensions as said button face and said aperture being adapted to allow said button to extend therethrough;
said mounting plate being adapted to receive and retain said base therein;
said mounting plate being adapted to being attached to a mounting surface with mounting hardware;
a first receiver for receiving said RF signal from said first radio-frequency transmitter;
said first receiver having an output side for generation a first receiver output signal; and
a relay having at least two positions for changing the operating state of an electrical appliance connected thereto;
said relay having an input side electrically connected to said output side of said first receiver;
wherein said relay changes from one position to another position in response to said first receiver output signal.
